(19) United States
(12) Patent Application Publication
(10) Pub. No.: US 2017/0301617 A1
(43) Pub. Date: Oct. 19, 2017

(54) LEADFRAME SUBSTRATE WITH ISOLATOR INCORPORATED THEREIN AND SEMICONDUCTOR ASSEMBLY AND MANUFACTURING METHOD THEREOF

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/642,253

(22) Filed: Jul. 5, 2017

Related U.S. Application Data
(63) Continuation-in-part of application No. 14/621,332, filed on Feb. 12, 2015.
Application No. 14/621,332 is a continuation-in-part of application No. 14/846,987, filed on Sep. 7, 2015.
Application No. 14/846,987 is a continuation-in-part of application No. 14/621,332, filed on Feb. 12, 2015.
(60) Provisional application No. 61/949,652, filed on Mar. 7, 2014.

(51) Int. Cl. H01L 23/498; H05K 1/02; H01L 23/31; H05K 3/44; H01L 23/00; H01L 21/3205

(52) U.S. Cl. CPC H01L 23/49861; H05K 1/0204; H01L 23/3107; H05K 3/44; H01L 24/81; H01L 24/85; H01L 24/17; H01L 24/49; H01L 2924/3511; H01L 2924/35121

(57) ABSTRACT

The leadframe substrate includes an isolator incorporated with metal leads by a compound layer. The metal leads are disposed about sidewalls of the isolator and provide horizontal and vertical routing for a semiconductor device to be assembled on the isolator. The compound layer covers the sidewalls of the isolator and fills in spaces between the metal leads, and provides robust mechanical bonds between the metal leads and the isolator.

### CROSS REFERENCE TO RELATED APPLICATIONS

This application is a continuation-in-part of U.S. application Ser. No. 14/621,332 filed Feb. 12, 2015 and a continuation-in-part of U.S. application Ser. No. 14/846,987 filed Sep. 7, 2015, each of which is hereby incorporated by reference.

### FIELD OF THE INVENTION

The present invention relates to a leadframe substrate and, more particularly, to a leadframe substrate having an isolator incorporated with metal leads, and a semiconductor assembly and a manufacturing method thereof.

### DESCRIPTION OF RELATED ART

High voltage or high current applications such as power module or light emitting diode (LED) often require high performance wiring board for signal interconnection. However, as the power increases, large amount of heat generated by semiconductor chip would degrade device performance and impose thermal stress on the chip. Ceramic material, such as alumina or aluminum nitride which is thermally conductive, electrically insulative and low in CTE (Coefficient of Thermal Expansion), is often considered as a suitable material for such kind of applications. U.S. Pat. Nos. 8,895,998 and 7,670,872 disclose various interconnect structures using ceramic as chip attachment pad material for better reliability. In addition, direct bond copper (DBC) board has become the preferred wiring board for many high power module applications. DBC board typically consists of a ceramic isolator such as Al₂O₃ (aluminium oxide), MN (aluminium nitride), or Si₃N₄ (silicon nitride) onto which copper layers are double-sided bonded through a high temperature melting and diffusion process. However, the attachment of a thick copper plate to the isolator often requires a very high fusing temperature in a stringent atmosphere, the need of having specific material or conditions to achieve a reliable copper/ceramic interface is tedious, which decreases the manufacturing yield and increases the process complexity. Furthermore, metallization of DBC often requires equal thickness of copper plates fusing at both sides to prevent ceramic plate warpage. While the bottom copper is desirably kept thick and planar as heat spreader, the top copper suffers poor etching resolution due to its thickness which severely limits circuitry routing capability. As a result, conventional DBC boards are not suitable for flip chip or surface mount attachment which is highly desirable for power module assembly.

### SUMMARY OF THE INVENTION

A primary objective of the present invention is to provide a leadframe substrate having a low-CTE and high thermal conductivity isolator incorporated therein so as to resolve the chip/board CTE mismatch problem, thereby improving the mechanical reliability and thermal character of the semiconductor assembly.

Another objective of the present invention is to provide a leadframe substrate having a plurality of metal leads disposed about the isolator, thereby allowing devices assembled on the isolator to be electrically connected to the external environment through the metal leads of the leadframe substrate.

Yet another objective of the present invention is to provide a leadframe substrate optionally having a routing circuitry disposed on a compound layer that covers sidewalls of the isolator. The compound layer provides dielectric platform and mechanical binding between the isolator and the metal leads, whereas the routing circuitry disposed on the compound layer can further improve electrical characteristics of the semiconductor assembly.

In accordance with the foregoing and other objectives, the present invention provides a leadframe substrate with an isolator incorporated therein, comprising: an isolator that includes a thermally conductive and electrically insulating slug; a plurality of metal leads that are disposed about and spaced from sidewalls of the isolator, wherein the metal leads each have an inner end directed toward the sidewalls of the isolator and an outer end situated farther away from the isolator than the inner end; and a compound layer that covers the sidewalls of the isolator and fills in spaces between the metal leads, wherein the compound layer has a top surface substantially coplanar with top sides of the isolator and the metal leads. Further, the present invention also provides a semiconductor assembly that includes a semiconductor device mounted over the top side of the isolator of the aforementioned leadframe substrate and electrically connected to the metal leads.

In another aspect, the present invention provides a method of making a leadframe substrate with an isolator incorporated therein, comprising: providing a leadframe that includes a metal frame and a plurality of metal leads, wherein the metal leads are integrally connected to the metal frame and each of them has an inner end directed toward a predetermined area within the metal frame; disposing an isolator at the predetermined area within the metal frame, wherein the isolator includes a thermally conductive and electrically insulating slug and is disposed about and spaced from the inner ends of the metal leads; providing a compound layer that covers sidewalls of the isolator and fills in spaces between the metal leads, wherein the compound layer has a top surface substantially coplanar with top sides of the isolator and the metal leads; and cutting off the metal frame from the metal leads after provision of the compound layer.

Unless specifically indicated or using the term “then” between steps, or steps necessarily occurring in a certain order, the sequence of the above-mentioned steps is not limited to that set forth above and may be changed or reordered according to desired design.

The leadframe substrate, the semiconductor assembly and the method of making the same according to the present invention have numerous advantages. For instance, disposing the metal leads about the isolator can provide flexible routing in the horizontal direction and vertical connecting channels between two opposites side of the leadframe substrate. Binding the compound layer to the leadframe and the isolator not only provides mechanical bonds between the isolator and the leadframe, but also offers a platform for high resolution circuitries disposed thereon, thereby allowing fine pitch assemblies such as flip chip and surface mount component to be assembled on the isolator and interconnected to the metal leads.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are top perspective and top plan views, respectively, of a leadframe in accordance with the first embodiment of the present invention;

FIG. 3 is a cross-sectional view taken along the line A-A in FIG. 2;

FIGS. 4 and 5 are top perspective and top plan views, respectively, of the structure of FIGS. 1 and 2 further provided with an isolator in accordance with the first embodiment of the present invention;

FIG. 6 is a cross-sectional view taken along the line A-A in FIG.

FIGS. 7 and 8 are top perspective and top plan views, respectively, of the structure of FIGS. 4 and 5 further provided with a compound layer in accordance with the first embodiment of the present invention;

FIG. 9 is a cross-sectional view taken along the line A-A in FIG. 8;

FIGS. 10 and 11 are top and bottom plan views, respectively, of the structure of FIGS. 7 and 8 further provided with a solder mask material, a top bonding layer and a bottom bonding layer in accordance with the first embodiment of the present invention;

FIG. 12 is a cross-sectional view taken along the line A-A in FIG. 10;

FIG. 13 is a top perspective view of a molded leadframe panel in accordance with the first embodiment of the present invention;

FIG. 14 is a top perspective view of a leadframe substrate singulated from the molded leadframe panel of FIG. 13 in accordance with the first embodiment of the present invention;

FIGS. 15 and 16 are cross-sectional and top plan views, respectively, of the structure of FIG. 14 further provided with a semiconductor device in accordance with the first embodiment of the present invention;

FIGS. 17 and 18 are top perspective and top plan views, respectively, of a leadframe in accordance with the second embodiment of the present invention;

FIG. 19 is a cross-sectional view taken along the line A-A in FIG. 18;

FIGS. 20 and 21 are top perspective and top plan views, respectively, of the structure of FIGS. 17 and 18 further provided with an isolator in accordance with the second embodiment of the present invention;

FIG. 22 is a cross-sectional view taken along the line A-A in FIG. 21;

FIGS. 23 and 24 are top perspective and cross-sectional views, respectively, of the structure of FIGS. 20 and 21 further provided with an compound layer in accordance with the second embodiment of the present invention;

FIG. 25 is a top plan view of a leadframe substrate trimmed from the structure of FIGS. 23-24 in accordance with the second embodiment of the present invention;

FIGS. 26 and 27 are top and bottom plan views, respectively, of a leadframe in accordance with the third embodiment of the present invention;

FIG. 28 is a cross-sectional view taken along the line A-A in FIG. 26;

FIGS. 29 and 30 are top and bottom plan views, respectively, of the structure of FIGS. 26 and 27 further provided with an isolator in accordance with the third embodiment of the present invention;

FIG. 31 is a cross-sectional view taken along the line A-A in FIG. 29;

FIGS. 32 and 33 are top and bottom plan views, respectively, of the structure of FIGS. 29 and 30 further provided with a compound layer in accordance with the third embodiment of the present invention;

FIG. 34 is a cross-sectional view taken along the line A-A in FIG. 32;

FIG. 35 is a top plan view of a leadframe substrate trimmed from the structure of FIGS. 32-34 in accordance with the third embodiment of the present invention;

FIG. 36 is a cross-sectional view taken along the line A-A in FIG. 35;

FIG. 37 is a cross-sectional view of another aspect of the leadframe substrate in accordance with the third embodiment of the present invention;

FIG. 38 is a cross-sectional view of yet another aspect of the leadframe substrate in accordance with the third embodiment of the present invention;

FIGS. 39 and 40 are top and bottom plan views, respectively, of yet another aspect of the leadframe substrate in accordance with the third embodiment of the present invention;

FIG. 41 is a cross-sectional view taken along the line A-A in FIG. 39;

FIGS. 42 and 43 area top and bottom plan views, respectively, of yet another aspect of the leadframe substrate in accordance with the third embodiment of the present invention;

FIG. 44 is a cross-sectional view taken along the line A-A in FIG. 42;

FIG. 45 is a top plan view of a leadframe in accordance with the fourth embodiment of the present invention;

FIG. 46 is a cross-sectional view taken along the line A-A in FIG. 45;

FIG. 47 is a top plan view of the structure of FIG. 45 further provided with an isolator in accordance with the fourth embodiment of the present invention;

FIG. 48 is a cross-sectional view taken along the line A-A in FIG. 47;

FIGS. 49 and 50 are top and bottom plan views, respectively, of the structure of FIG. 47 further provided with a compound layer in accordance with the fourth embodiment of the present invention;

FIG. 51 is a cross-sectional view taken along the line A-A in FIG. 49;

FIGS. 52 and 53 are top plan and cross-sectional views, respectively, of the structure of FIGS. 49-51 further provided with a routing circuitry in accordance with the fourth embodiment of the present invention;

FIG. 54 is a bottom plan view of a leadframe substrate trimmed from the structure of FIGS. 52-53 in accordance with the fourth embodiment of the present invention;

FIG. 55 is a cross-sectional view of the structure of FIG. 54 further provided with a semiconductor device and passive components in accordance with the fourth embodiment of the present invention;

FIGS. 56 and 57 are top and bottom plan views, respectively, of the structure with an isolator placed with a leadframe in accordance with the fifth embodiment of the present invention;

FIG. 58 is a cross-sectional view taken along the line A-A in FIG. 56;

FIGS. 59 and 60 are top and bottom plan views, respectively, of the structure of FIGS. 56-57 further provided with a compound layer in accordance with the fifth embodiment of the present invention;

FIG. 61 is a cross-sectional view taken along the line A-A in FIG. 59;

FIGS. 62 and 63 are top and bottom plan views, respectively, of a leadframe substrate trimmed from the structure of FIGS. 59-60 in accordance with the fifth embodiment of the present invention;

FIG. 64 is a cross-sectional view taken along the line A-A in FIG. 62;

FIG. 65 is a cross-sectional view of the structure of FIG. 64 further provided with a first semiconductor device and a passive component in accordance with the fifth embodiment of the present invention;

FIG. 66 is a cross-sectional view of the structure of FIG. 65 further provided with a second semiconductor device in accordance with the fifth embodiment of the present invention;

FIG. 67 is a cross-sectional view of the structure of FIG. 66 further provided with an encapsulant in accordance with the fifth embodiment of the present invention;

FIG. 68 is a top plan view of another aspect of the leadframe substrate in accordance with the fifth embodiment of the present invention;

FIG. 69 is a cross-sectional view taken along the line A-A in FIG. 68;

FIGS. 70 and 71 are top and bottom plan views, respectively, of a leadframe in accordance with the sixth embodiment of the present invention;

FIG. 72 is a cross-sectional view taken along the line A-A in FIG. 70;

FIGS. 73 and 74 are top and bottom plan views, respectively, of the structure of FIGS. 70 and 71 further provided with an isolator in accordance with the sixth embodiment of the present invention;

FIG. 75 is a cross-sectional view taken along the line A-A in FIG. 73;

FIGS. 76 and 77 are top and bottom plan views, respectively, of the structure of FIGS. 73 and 74 further provided with a compound layer in accordance with the sixth embodiment of the present invention;

FIG. 78 is a cross-sectional view taken along the line A-A in FIG. 76;

FIGS. 79 and 80 are top and bottom plan views, respectively, of a leadframe substrate trimmed from the structure of FIGS. 76-77 in accordance with the sixth embodiment of the present invention;

FIG. 81 is a cross-sectional view taken along the line A-A in FIG. 79;

FIGS. 82 and 83 are cross-sectional and top plan views, respectively, of the structure of FIGS. 79-81 further provided with a first semiconductor device, a second semiconductor device and a passive component in accordance with the sixth embodiment of the present invention;

FIG. 84 is a cross-sectional view of another aspect of the leadframe substrate in accordance with the sixth embodiment of the present invention;

FIG. 85 is a top perspective view of the structure with an isolator placed within a leadframe in accordance with the seventh embodiment of the present invention;

FIG. 86 is a top perspective view of the structure of FIG. 85 further provided with a compound layer in accordance with the seventh embodiment of the present invention;

FIG. 87 is a top perspective view of the structure of FIG. 86 further provided with a routing circuitry in accordance with the seventh embodiment of the present invention;

FIG. 88 is a top perspective view of the structure of FIG. 87 further provided with a semiconductor device and passive components in accordance with the seventh embodiment of the present invention;

FIG. 89 is a top perspective view of the structure of FIG. 88 further provided with an encapsulant in accordance with the seventh embodiment of the present invention;

FIGS. 90, 91 and 92 are cross-sectional, top perspective and bottom perspective views, respectively, of a semiconductor assembly trimmed from the structure of FIG. 89 in accordance with the seventh embodiment of the present invention; and

FIGS. 93 and 94 are cross-sectional and bottom perspective reviews, respectively, of a semiconductor assembly in accordance with the eighth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

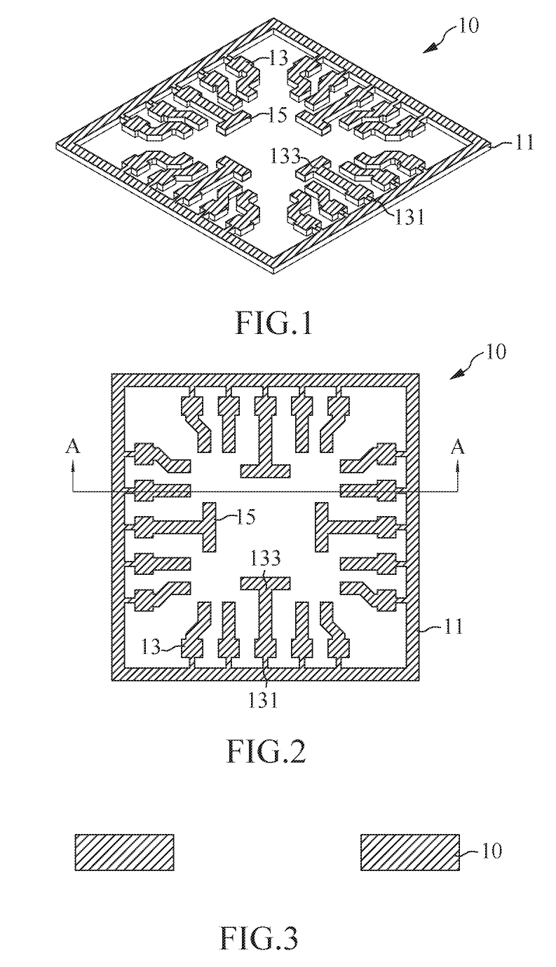

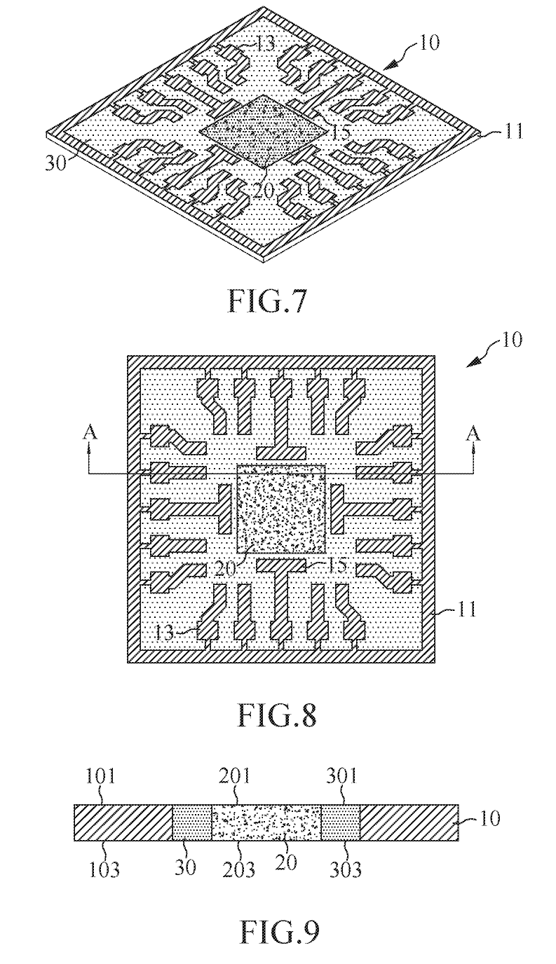

FIGS. 1-14 are schematic views showing a method of making a leadframe substrate that includes an isolator, a plurality of metal leads, an alignment guide, a compound layer, a solder mask material, a top bonding layer and a bottom bonding layer in accordance with the first embodiment of the present invention.

FIGS. 1, 2 and 3 are top perspective, top plan and cross-sectional views, respectively, of a leadframe 10. The leadframe 10 typically is made of copper alloys, steel or alloy 42, and can be formed by wet etching or stamping/punching process from a rolled metal strip. The etching process may be a one-sided or two-sided etching to etch through the metal strip and thereby transfers the metal strip into a desired overall pattern of the leadframe 10. In this embodiment, the leadframe 10 has a uniform thickness in a range from about 0.15 mm to about 1.0 mm, and includes a metal frame 11, a plurality of metal leads 13 and an alignment guide 15. The metal leads 13 laterally extend from the metal frame 11 toward the central area within the metal frame 11. As a result, the metal leads 13 each have an outer end 131 integrally connected to interior sidewalls of the metal frame 11 and an inner end 133 directed inwardly away from the metal frame 11. The alignment guide 15 is integrally connected to the inner ends 133 of the metal leads 13, and surrounds a predetermined area for the placement of a subsequently disposed isolator. In this illustration, the alignment guide 15 consists of plural strips in a rectangular frame array and conforms to four lateral sides of a subsequently disposed isolator. However, the alignment guide pattern is not limited thereto, and can be other various patterns against undesirable movement of the subsequently disposed isolator.

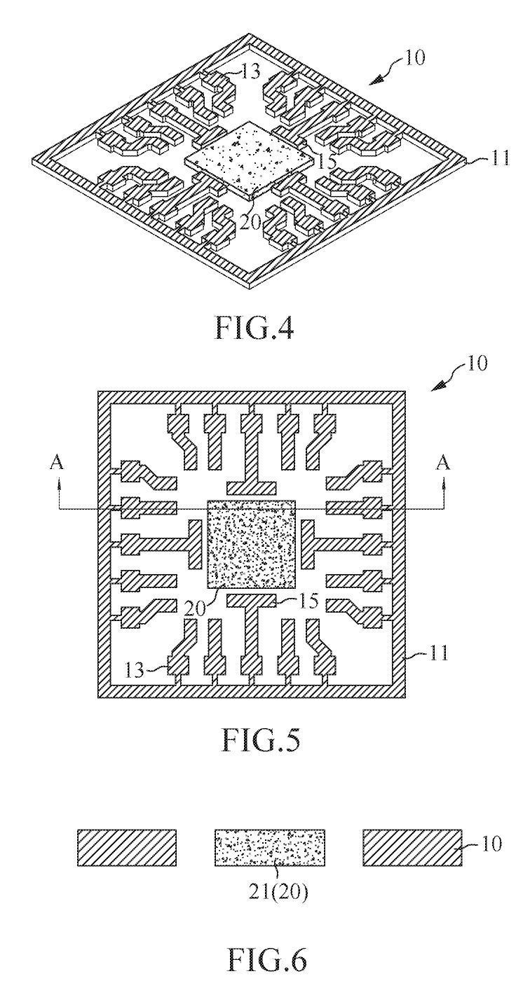

FIGS. 4, 5 and 6 are top perspective, top plan and cross-sectional views, respectively, of the structure with an isolator 20 disposed at the predetermined area surrounded by the alignment guide 15. The isolator 20 is a thermally conductive and electrically insulating slug 21 that typically has high elastic modulus and low coefficient of thermal expansion (for example, 2×10⁻⁶ K⁻¹ to 10×10⁻⁶ K⁻¹), such as ceramic, silicon, glass or others. In this embodiment, the isolator 20 is a ceramic slug having a thickness substantially equal to the thickness of the leadframe 10. The isolator 20 is placed at the central area within the metal frame 11, with the alignment guide 15 laterally aligned with the peripheral edges of the isolator 20. The isolator placement accuracy is provided by the alignment guide 15. As the alignment guide 15 is in close proximity to and conforms to the four lateral surfaces of the isolator 20 in lateral directions, any undesirable movement of the isolator 20 can be avoided. In some cases, the isolator 20 can also be placed within the metal frame 11 and surrounded by the inner ends 133 of the metal leads 13 without the alignment guide 15 about the peripheral edges of the isolator 20.

FIGS. 7, 8 and 9 are top perspective, top plan and cross-sectional views, respectively, of the structure provided with a compound layer 30. The compound layer 30 can be deposited by applying a molding material into the remaining spaces within the metal frame 11. The molding material can be applied by paste printing, compressive molding, transfer molding, liquid injection molding, spin coating, or other suitable methods. Then, a thermal process (or heat-hardened process) is applied to harden the molding material and to transform it into a solid molding compound. As a result, the compound layer 30 laterally covers and surrounds and conformally coats the metal leads 13, the alignment guide 15 and the isolator 20 in lateral directions. By planarization, the compound layer 30 has a top surface 301 substantially coplanar with top side 101 of the leadframe 10 and the top side 201 of the isolator 20, and a bottom surface 303 substantially coplanar with bottom side 103 of the leadframe 10 and the bottom side 203 of the isolator 20.

The compound layer 30 typically includes binder resins, fillers, hardeners, diluents, and additives. There is no particular limit to the binder resin that can be used in accordance with the present invention. For example, the binder resin may be at least one selected from the group consisting of an epoxy resin, a phenol resin, a polyimide resin, a polyurethane resin, a silicone resin, a polyester resin, an acrylate, bismaleimide (BMI), and equivalents thereof. The binder resin provides intimate adhesion between an adherent and the filler. The binder resin also serves to elicit thermal conductivity through chain-like connection of the filler. The binder resin may also improve physical and chemical stability of the molding compound.

Additionally, there is no particular limit to the filler that can be used in accordance with the present invention. For example, a thermally conductive filler may be selected from the group consisting of aluminum oxide, aluminum nitride, silicon carbide, tungsten carbide, boron carbide, silica and equivalents thereof. More specifically, the compound layer 30 may become thermally conductive or low in CTE if suitable fillers are dispersed therein. For example, aluminum nitride (AlN) or silicon carbide (SiC) has relatively high thermal conductivity, high electrical resistance, and a relatively low coefficient of thermal expansion (CTE). Accordingly, when the compound layer 30 employs these kinds of materials as fillers, the compound layer 30 would exhibit improved heat dissipation performance, electrical isolation performance and shows inhibition of delamination or cracking of circuitry or interfaces due to low CTE. The maximum particle size of the thermally conductive filler may be 25 μm or less. The content of the filler may be in the range of 10 to 90% by weight. If the content of the thermally conductive filler is less than 10% by weight, this may result in insufficient thermal conductivity and excessively low viscosity. Low viscosity means that it may be difficult to handle and control the process due to excessively easy outflow of the resin from the tool during dispensing or molding process. On the other hand, if the content of the filler is higher than 90% by weight, this may result in decreased adhesive strength and excessively high viscosity of the molding material. High viscosity of the molding material results in poor workability due to no outflow of the material from the tool during the dispensing or molding process. Additionally, the compound layer 30 may include more than one type of fillers. For example, the second filler may be polytetrafluoroethylene (PTFE) so as to further improve electrical isolation property of the compound layer 30. In any case, the compound layer 30 preferably has an elastic modulus larger than 1.0 GPa and a linear coefficient of thermal expansion in a range from about 5×10⁻⁶ K⁻¹ to about 15×10⁻⁶ K⁻¹.

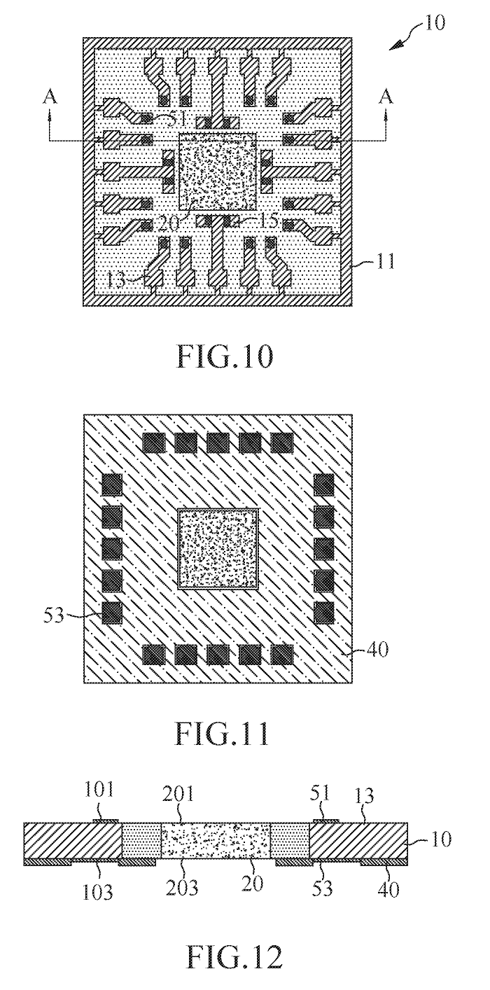

FIGS. 10, 11 and 12 are top plan, bottom plan and cross-sectional views, respectively, of the structure provided with a solder mask material 40, a top bonding layer 51 and a bottom bonding layer 53. Optionally, the solder mask material 40 can be provided to cover the bottom side of the structure, and includes solder mask openings to expose the isolator 20 and selected portions of the metal leads 13 from below. Additionally, the top side 101 and the bottom side 103 of the leadframe 10 may be further selectively plated with the top bonding layer 51 and the bottom bonding layer 53, respectively. The top bonding layer 51 and the bottom bonding layer 53 may be made of gold, lead-tin solder, tin, nickel, palladium, or any bondable or solderable metal. In this illustration, the top bonding layer 51 is deposited on selected portions of the metal leads 13 and the alignment guide 15 from above, whereas the bottom bonding layer 53 is deposited on the exposed portions of the metal leads 13 from below.

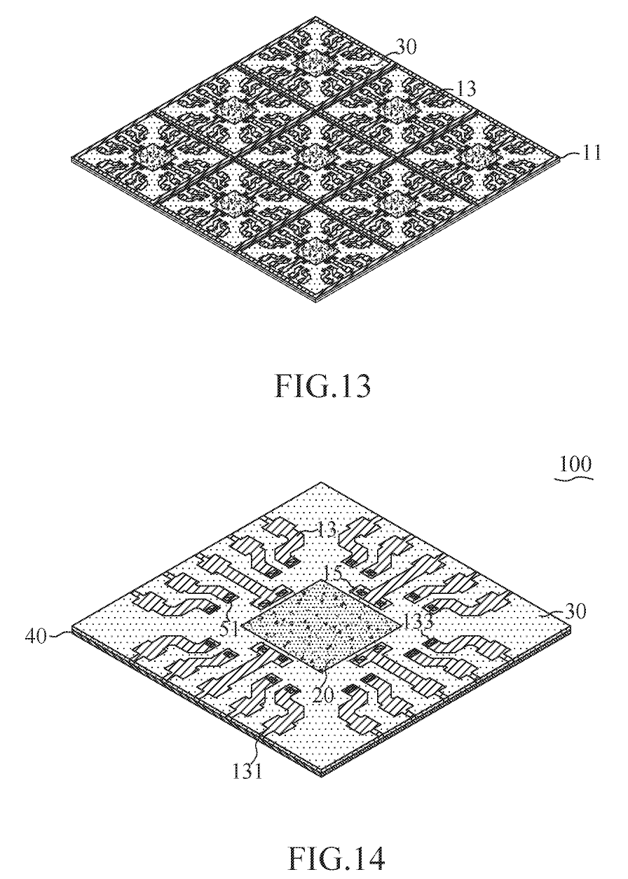

FIG. 13 is a top perspective view of a molded leadframe panel having multiple leadframe units connected with each other in a 3×3 array. Actually, the above-illustrated steps of FIGS. 1-12 typically are performed on a panel scale to form the molded leadframe panel consisting of multiple units each corresponding to the structure illustrated in FIGS. 10-12.

FIG. 14 is a top perspective view of a leadframe substrate 100 singulated from the molded leadframe panel. By a rotating saw or a trimming machine, the molded leadframe panel is singulated into a plurality of individual leadframe substrates 100 by cutting off the metal frame 11 from the outer ends 131 of the metal leads 13. Accordingly, the outer ends 131 of the metal leads 13 are situated at peripheral edges of the leadframe substrate 100 and have a lateral surface flush with peripheral edges of the compound layer 30.

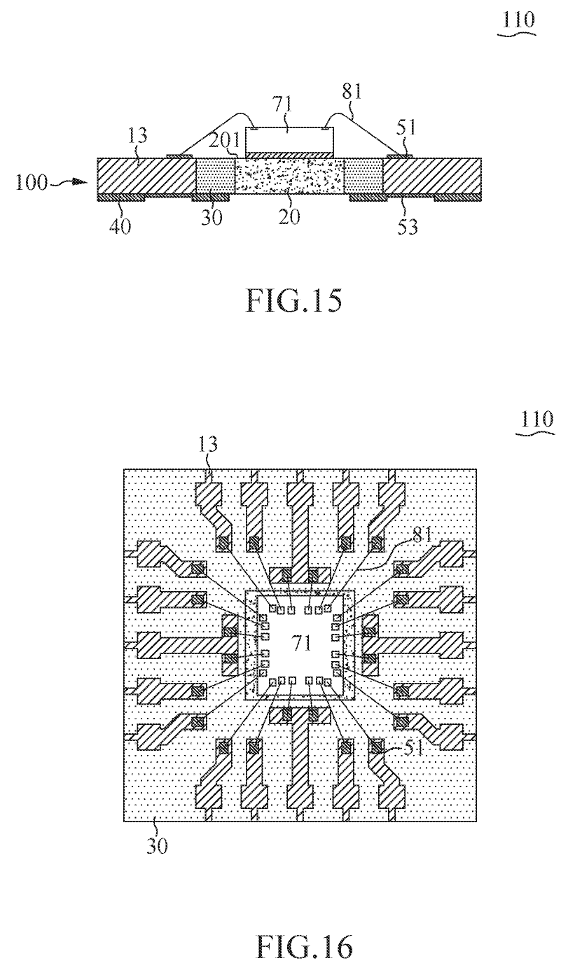

FIGS. 15 and 16 are cross-sectional and top plan views, respectively, of a semiconductor assembly 110 with a semiconductor device 71 electrically connected to the leadframe substrate 100 illustrated in FIG. 14. The semiconductor device 71, illustrated as a chip, is mounted on the top side 201 of the isolator 20 and electrically connected to the metal leads 13 through bonding wires 81 in contact with the top bonding layer 51.

### Embodiment 2

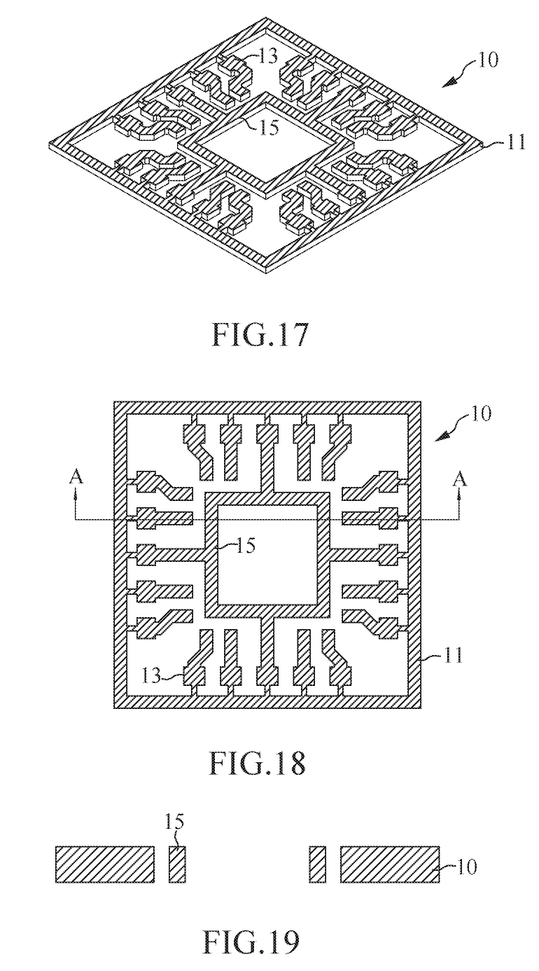

FIGS. 17-25 are schematic views showing a method of making a leadframe substrate having the isolator surrounded by a ground ring in accordance with the second embodiment of the present invention.

For purposes of brevity, any description in Embodiment 1 is incorporated herein insofar as the same is applicable, and the same description need not be repeated.

FIGS. 17, 18 and 19 are top perspective, top plan and cross-sectional views, respectively, of a leadframe 10. The leadframe 10 is similar to that illustrated in FIGS. 1-3, except that the alignment guide 15 is shaped into a rectangular ring as a ground ring.

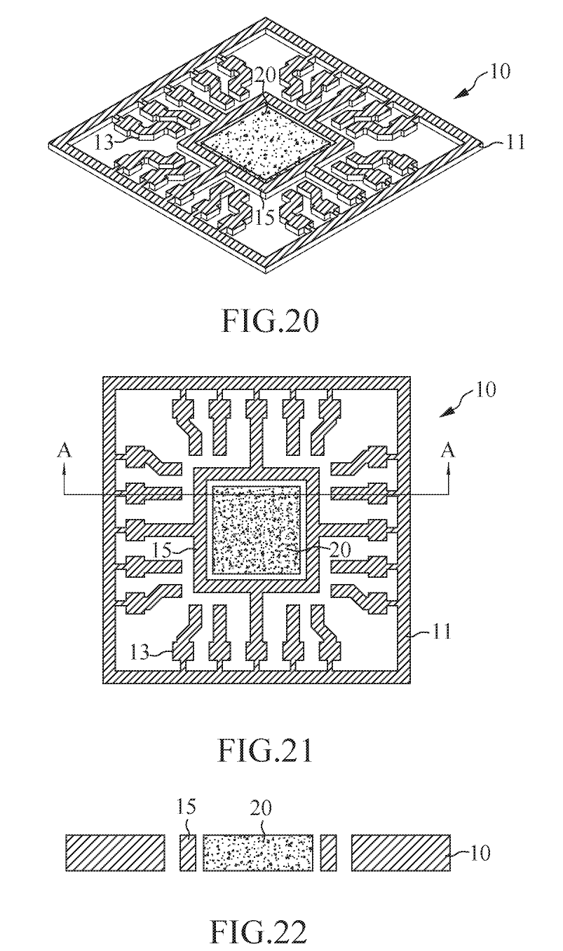

FIGS. 20, 21 and 22 are top perspective, top plan and cross-sectional views, respectively, of the structure with an isolator 20 disposed at the central area within the metal frame 11. The isolator 20 is spaced from and laterally surrounded by the alignment guide 15.

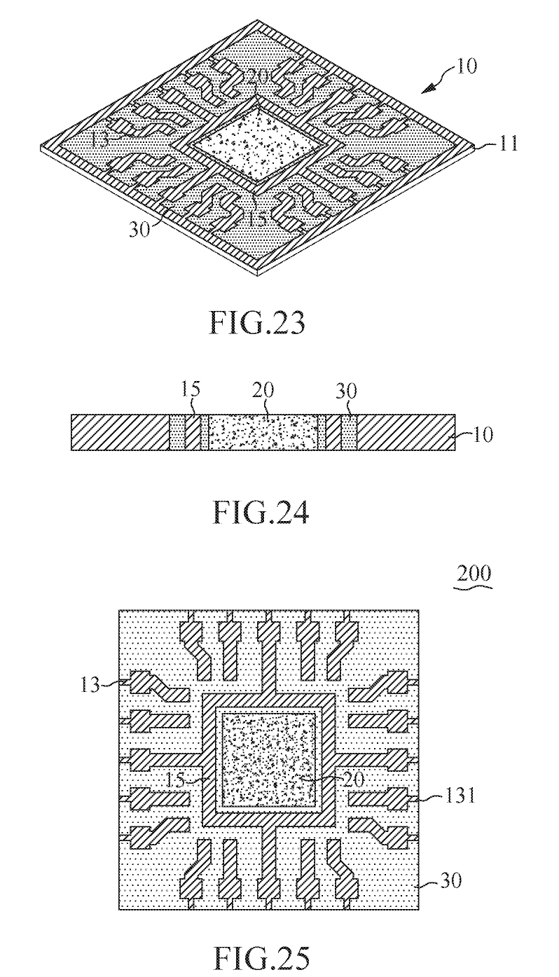

FIGS. 23 and 24 are top perspective and cross-sectional views, respectively, of the structure provided with a compound layer 30. The compound layer 30 covers sidewalls of the isolator 20 and fills in spaces between the metal leads 13. As a result, the compound layer 30 provides robust mechanical bonds between the leadframe 10 and the isolator 20.

FIG. 25 is a top plan view of the structure after removal of the metal frame 11. By cutting off the metal frame 11, the connection between the outer ends 131 of the metal leads 13 is broken. As a result, a leadframe substrate 200 is accomplished and includes metal leads 13, an alignment guide 15, an isolator 20 and a compound layer 30. In this embodiment, some of the metal leads 13 are integrated with the alignment guide 15 and provided for ground connection, whereas the others of the metal leads 13 are electrically isolated from each other and serve as signal leads.

### Embodiment 3

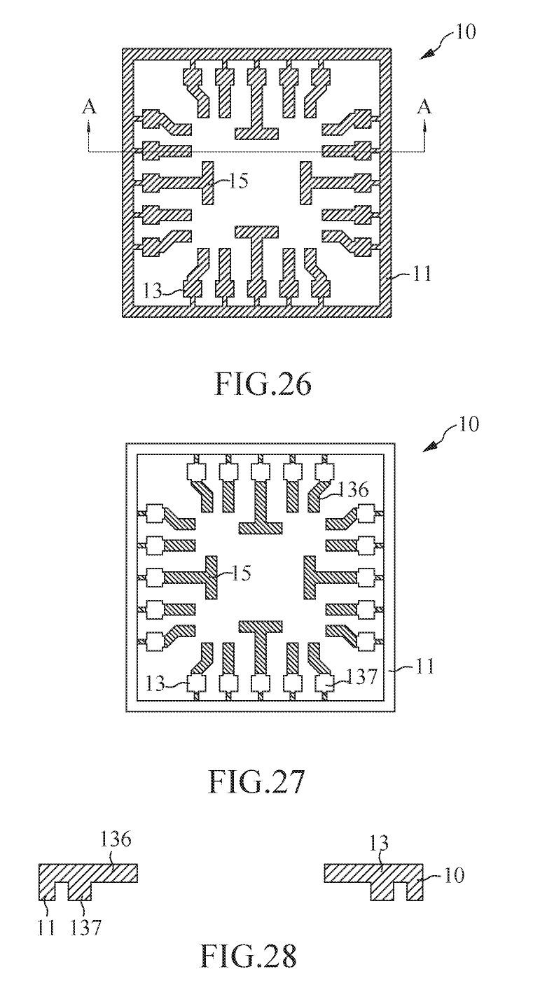

FIGS. 26-36 are schematic views showing a method of making a leadframe substrate in which the metal leads have a stepped cross-sectional profile in accordance with the third embodiment of the present invention.

For purposes of brevity, any description in Embodiments above is incorporated herein insofar as the same is applicable, and the same description need not be repeated.

FIGS. 26, 27 and 28 are top plan, bottom plan and cross-sectional views, respectively, of a leadframe 10. The leadframe 10 is similar to that illustrated in FIGS. 1-3, except that the metal leads 13 are further selectively half-etched from the bottom side. As a result, the metal leads 13 each have a stepped cross-sectional profile formed by a horizontally elongated portion 136 and a vertically projected portion 137. The horizontally elongated portion 136 has a smaller thickness than the metal frame 11, and laterally extends inwardly from the interior sidewalls of the metal frame 11. In this illustration, the horizontally elongated portion 136 has an upper surface flush with the top sides of the metal frame 11 and the alignment guide 15, whereas the vertically projected portion 137 protrudes from a lower surface of the horizontally elongated portion 136 in the downward direction and has an exterior surface flush with the bottom sides of the metal frame 11 and the alignment guide 15.

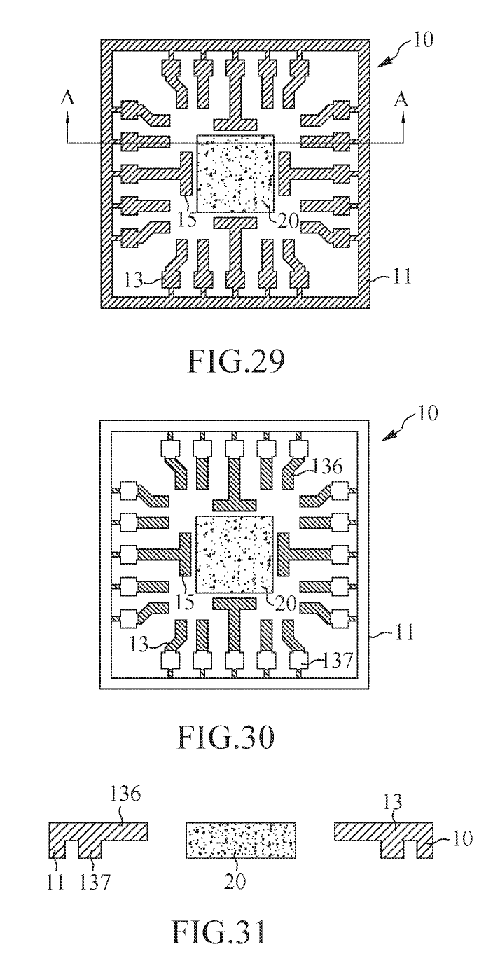

FIGS. 29, 30 and 31 are top plan, bottom plan and cross-sectional views, respectively, of the structure with an isolator 20 disposed at the central area within the metal frame 11. The isolator 20 is spaced from and laterally surrounded by the alignment guide 15, and has a thickness equal to the combined thickness of the horizontally elongated portion 136 and the vertically projected portion 137.

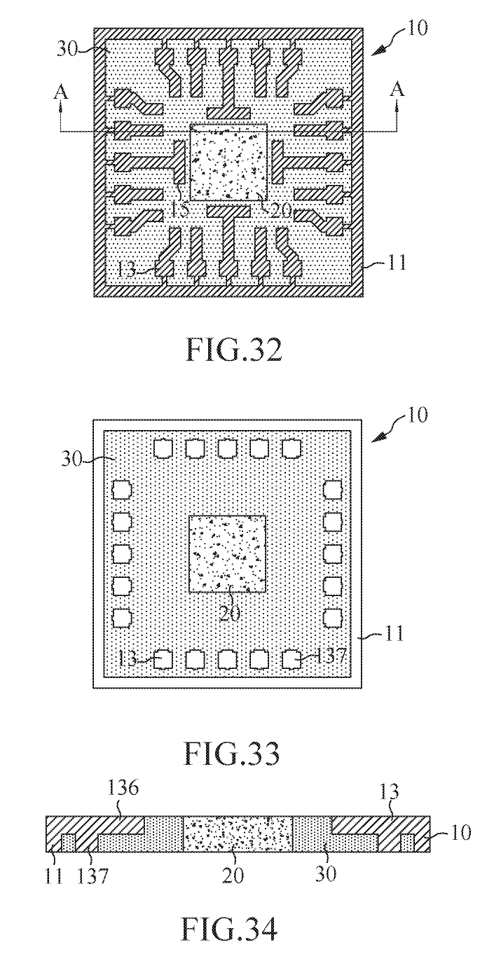

FIGS. 32, 33 and 34 are top plan, bottom plan and cross-sectional views, respectively, of the structure provided with a compound layer 30. The compound layer 30 fills in spaces between the metal leads 13 and between the alignment guide 15 and the isolator 20, and further covers the lower surface of the horizontally elongated portions 136 and sidewalls of the vertically projected portions 137. As a result, the metal leads 13 can securely interlock with the compound layer 30 so as to prevent the metal leads 13 from being vertically forced apart from the compound layer 30 and also to avoid micro-cracking at the interface along the vertical direction.

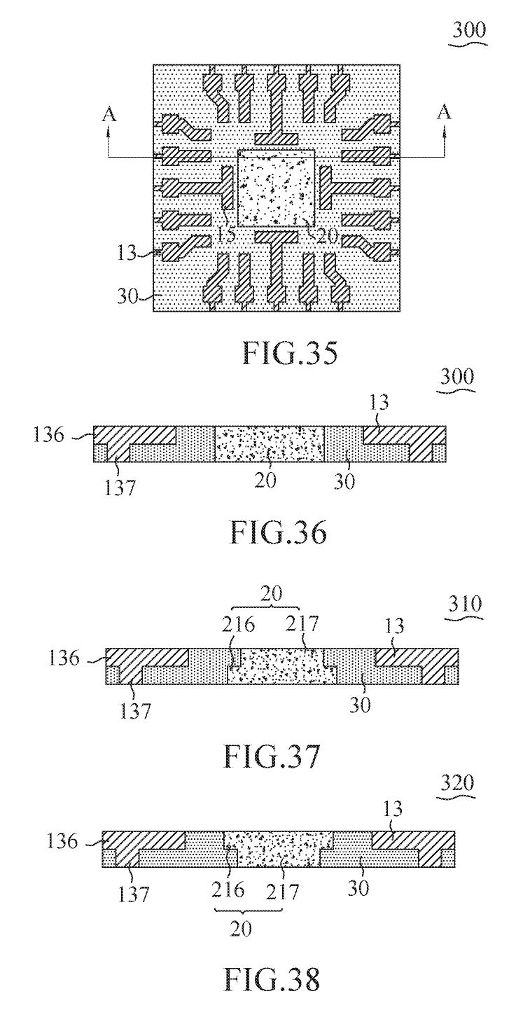

FIGS. 35 and 36 are top plan and cross-sectional views, respectively, of the structure after removal of the metal frame 11. By cutting off the metal frame 11, the metal leads 13 are electrically isolated from each other. As a result, a leadframe substrate 300 is accomplished and includes metal leads 13, an alignment guide 15, an isolator 20 and a compound layer 30.

FIG. 37 is a cross-sectional view of another aspect of the leadframe substrate according to the third embodiment of the present invention. The leadframe substrate 310 is similar to that illustrated in FIG. 36, except that the isolator 20 has a stepped cross-sectional profile formed by a base portion 216 and a post portion 217. The base portion 216 has a lager diameter than the post portion 217, and laterally extends beyond peripheral edges of the post portion 217. In this illustration, the base portion 216 has a lower surface flush with the bottom surface of the compound layer 30 and the exterior surface of the vertically projected portion 137, whereas the post portion 217 protrudes from an upper surface of the base portion 216 in the upward direction and has an exterior surface flush with the top surface of the compound layer 30 and the upper surface of the horizontally elongated portion 136. As a result, the stepped cross-sectional profile of the isolator 20 can prevent the isolator 20 from being vertically forced apart from the compound layer 30.

FIG. 38 is a cross-sectional view of yet another aspect of the leadframe substrate according to the third embodiment of the present invention. The leadframe substrate 320 is similar to that illustrated in FIG. 37, except that the post portion 217 protrudes from a lower surface of the base portion 216 in the downward direction. In this illustration, the base portion 216 has an upper surface flush with the top surface of the compound layer 30 and the upper surface of the horizontally elongated portion 136, whereas the post portion 217 has an exterior surface flush with the bottom surface of the compound layer 30 and the exterior surface of the vertically projected portion 137.

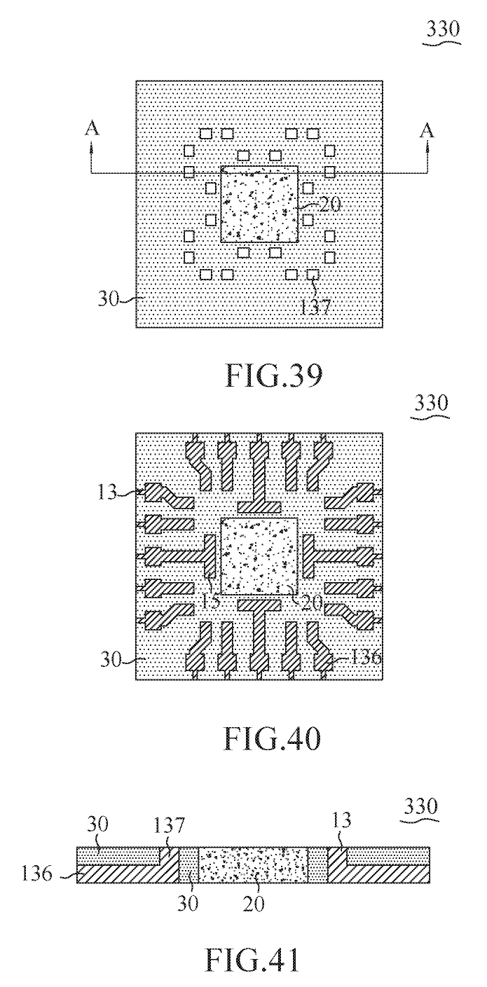

FIGS. 39, 40 and 41 are top plan, bottom plan and cross-sectional views, respectively, of yet another aspect of the leadframe substrate according to the third embodiment of the present invention. The leadframe substrate 330 is similar to that illustrated in FIGS. 35 and 36, except that the metal leads 13 and the alignment guide 15 are selectively half-etched from the top side. In this illustration, the horizontally elongated portions 136 of the metal leads 13 have a lower surface flush with the bottom surface of the compound layer 30, whereas the vertically projected portions 137 protrude from an upper surface of the horizontally elongated portions 136 in the upward direction and have an exterior surface flush with the top surface of the compound layer 30.

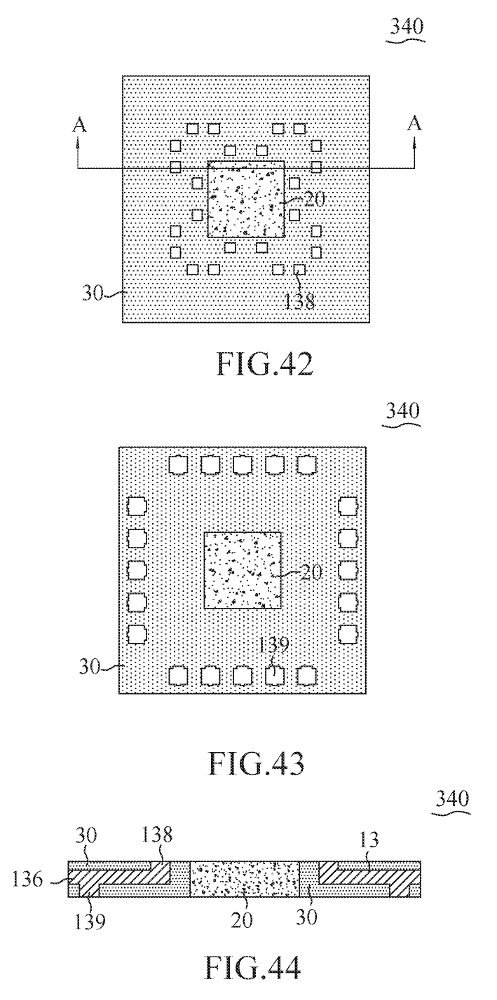

FIGS. 42, 43 and 44 are top plan, bottom plan and cross-sectional views, respectively, of yet another aspect of the leadframe substrate according to the third embodiment of the present invention. The leadframe substrate 340 is similar to that illustrated in FIGS. 35-36, except that the metal leads 13 and the alignment guide 15 are selectively half-etched from the top side and the bottom side. Accordingly, the metal leads 13 each have a horizontally elongated portion 136, a top vertically projected portion 138 and a bottom vertically projected portion 139. The upper and lower surfaces of the horizontally elongated portions 136 are covered by the compound layer 30. The top vertically projected portion 138 protrudes from the upper surface of the horizontally elongated portion 136 and has an external surface flush with the top surfaces of the isolator 20 and the compound layer 30. The bottom vertically projected portion 139 protrudes from the lower surface of the horizontally elongated portion 136 and has an external surface flush with the bottom surfaces of the isolator 20 and the compound layer 30.

### Embodiment 4

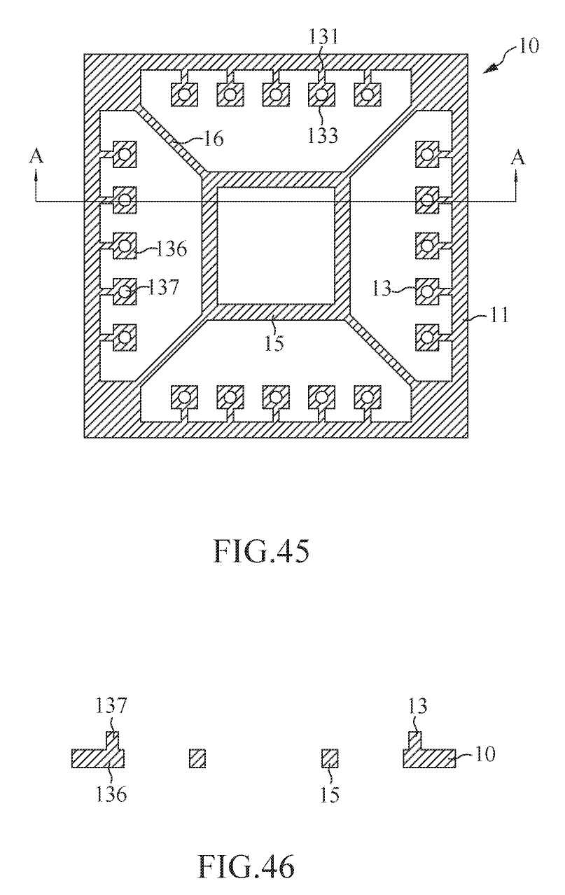

FIGS. 45-54 are schematic views showing a method of making a leadframe substrate having a routing circuitry electrically coupled to the metal leads in accordance with the fourth embodiment of the present invention.

For purposes of brevity, any description in Embodiments above is incorporated herein insofar as the same is applicable, and the same description need not be repeated.

FIGS. 45 and 46 are top plan and cross-sectional views, respectively, of a leadframe 10. The leadframe 10 includes a metal frame 11, a plurality of metal leads 13, an alignment guide 15 and a plurality of tie bars 16. The metal leads 13 each have an outer end 131 integrally connected to the metal frame 11 and an inner end 133 directed inwardly away from the metal frame 11. The alignment guide 15 surrounds the central area within the metal frame 11 and is connected to the metal frame 11 by the tie bars 16. In this embodiment, the leadframe 10 is further selectively half-etched from the top side thereof. As a result, the metal frame 11, the alignment guide 15 and the tie bars 16 have reduced thickness, and the metal leads 13 have a stepped cross-sectional profile formed by a horizontally elongated portion 136 and a vertically projected portion 137. In this illustration, the vertically projected portion 137 protrudes from an upper surface of the horizontally elongated portion 136 in the upward direction.

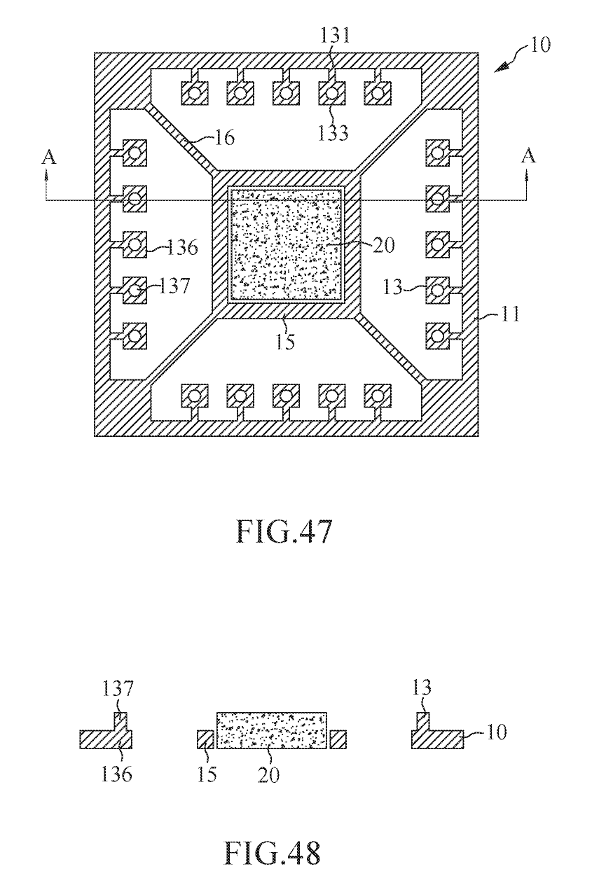

FIGS. 47 and 48 are top plan and cross-sectional views, respectively, of the structure with an isolator 20 disposed at the central area within the metal frame 11. The placement accuracy of the isolator 20 is provided by the alignment guide 15 in close proximity to sidewalls of the isolator 20. The thickness of the isolator 20 is larger than that of the metal frame 11, the alignment guide 15 and the tie bars 16, and is substantially equal to the combined thickness of the horizontally elongated portion 136 and the vertically projected portion 137.

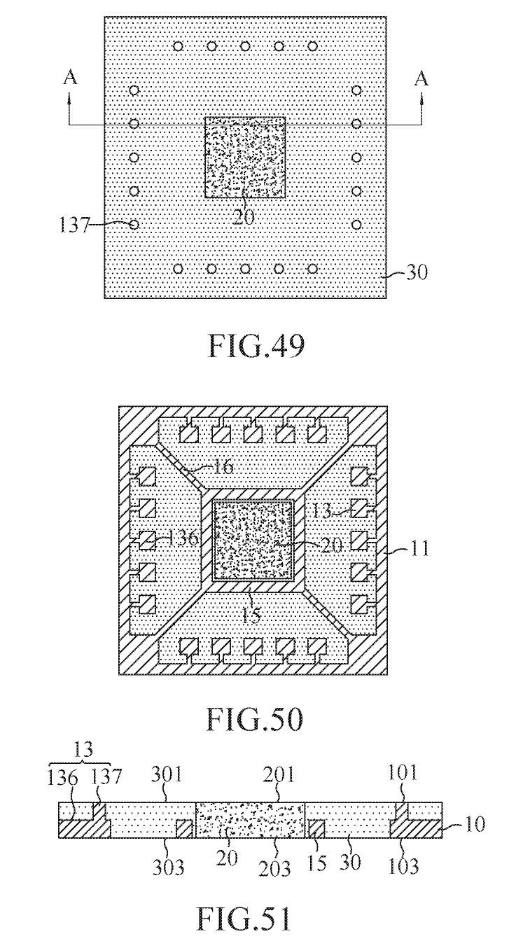

FIGS. 49, 50 and 51 are top plan, bottom plan and cross-sectional views, respectively, of the structure provided with a compound layer 30. The compound layer 30 fills in spaces between the metal leads 13 and between the alignment guide 15 and the isolator 20, and further covers the metal frame 11, the horizontally elongated portions 136 of the metal leads 13, the alignment guide 15 and the tie bars 16 from above. By planarization, the compound layer 30 has a top surface 301 substantially coplanar with the top side 101 of the metal leads 13 and the top side 201 of the isolator 20, and a bottom surface 303 substantially coplanar with the bottom side 103 of the metal leads 13 and the bottom side 203 of the isolator 20.

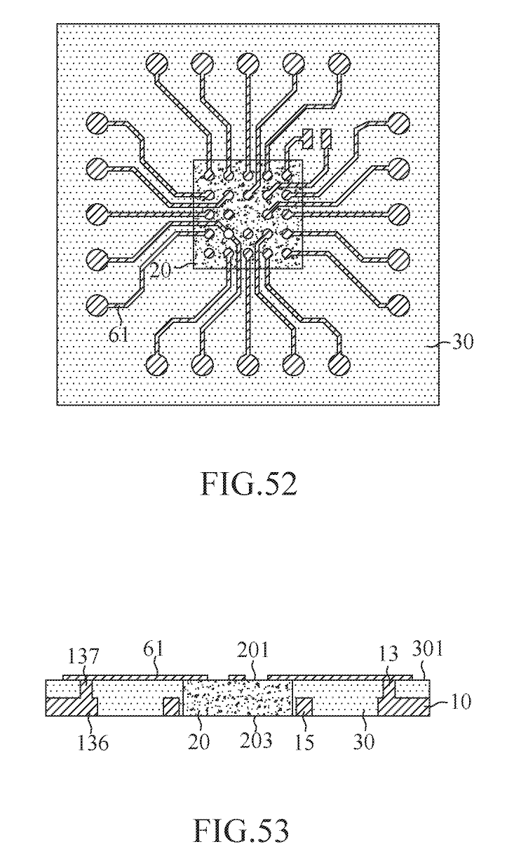

FIGS. 52 and 53 are top plan and cross-sectional views, respectively, of the structure provided with a routing circuitry 61 by metal pattern deposition described below. The top surface of the structure can be metallized to form an electrically conductive layer (typically a copper layer) as a single layer or multiple layers by numerous techniques, such as electroplating, electroless plating, evaporating, sputtering or their combinations. The electrically conductive layer can be made of Cu, Ni, Ti, Au, Ag, Al, their combinations, or other suitable electrically conductive material. Typically, a seeding layer is formed on the topmost surface of the structure prior to the electrically conductive layer is electroplated to a desirable thickness. The seeding layer may consist of a diffusion barrier layer and a plating bus layer. The diffusion barrier layer is to counterbalance oxidation or corrosion of the electrically conductive layer such as copper. In most cases, the diffusion barrier layer also acts as an adhesion promotion layer to the underlying material and is formed by physical vapor deposition (PVD) such as sputtered Ti or TiW with a thickness in a range from about 0.01 μm to about 0.1 μm. However, the diffusion barrier layer may be made of other materials, such as TaN, or other applicable materials and its thickness range is not limited to the range described above. The plating bus layer is typically made of the same material as the electrically conductive layer with a thickness in a range from about 0.1 μm to about 1 μm. For example, if the electrically conductive layer is copper, the plating bus layer would preferably be a thin film copper formed by physical vapor deposition or electroless plating. However, the plating bus layer may be made of other applicable materials such as silver, gold, chromium, nickel, tungsten, or combinations thereof and its thickness range is not limited to the range described above.

Following the deposition of the seeding layer, a photoresist layer (not shown) is formed over the seeding layer. The photoresist layer may be formed by a wet process, such as a spin-on process, or by a dry process, such as lamination of a dry film. After the photoresist layer is formed, the photoresist layer is patterned to formed openings, which are then filled with plated metal such as copper to form the routing circuitry 61. After metal plating, the exposed seeding layer is then removed by etching process to form electrically isolated conductive traces as desired. In this illustration, the routing circuitry 61 is a patterned metal layer and laterally extends on the top surface 301 of the compound layer 30 and the top side 201 of the isolator 20, and contacts and is electrically coupled to the vertically projected portions 137 of the metal leads 13.

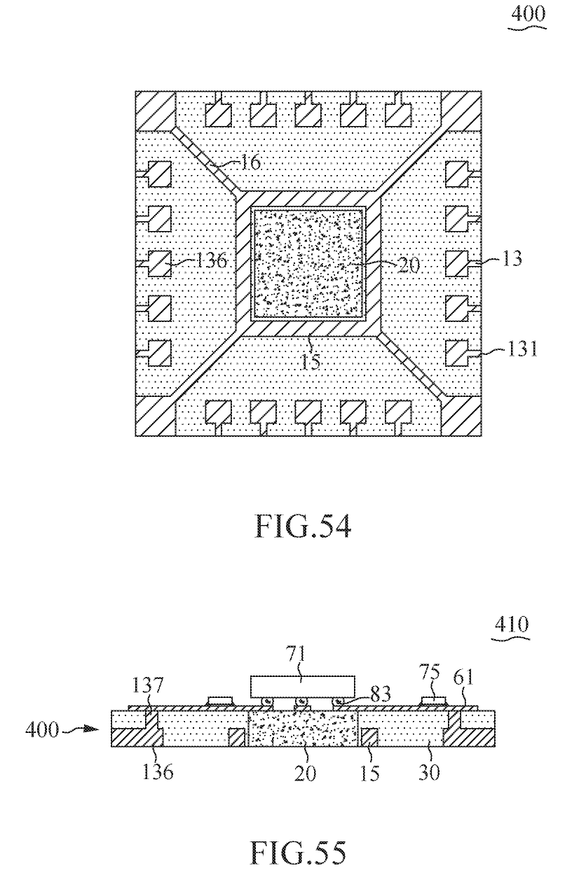

FIG. 54 is a bottom plan view of a leadframe substrate 400 separated from the metal frame 11. By cutting off the metal frame 11, the metal leads 13 are electrically isolated from each other and have outer ends 131 situated at peripheral edges of the leadframe substrate 400.

FIG. 55 is a cross-sectional view of a semiconductor assembly 410 with a semiconductor device 71 and passive components 75 electrically connected to the leadframe substrate 400. The semiconductor device 71 is flip-chip mounted over the top side of the isolator 20 and electrically coupled to the routing circuitry 61 via conductive bumps 83. The passive components 75 are mounted over the top surface of the compound layer 30 and electrically coupled to the routing circuitry 61.

### Embodiment 5

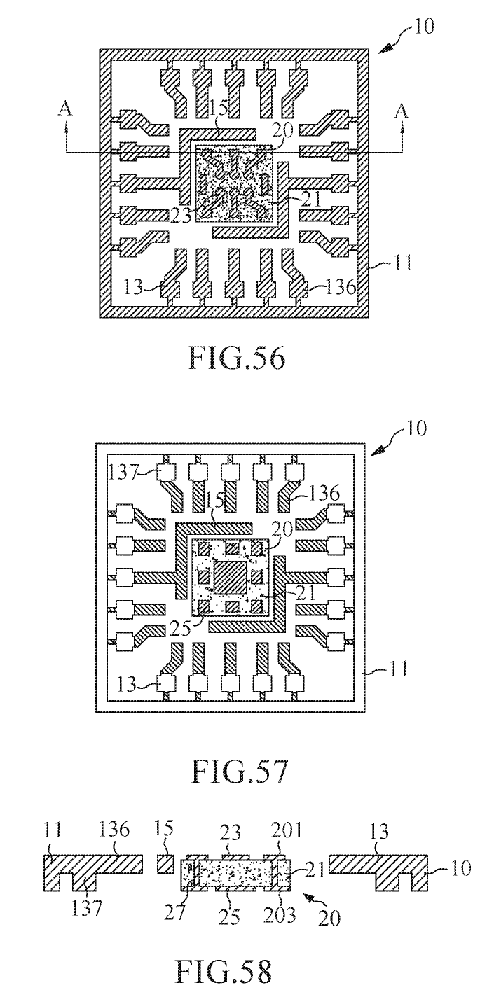

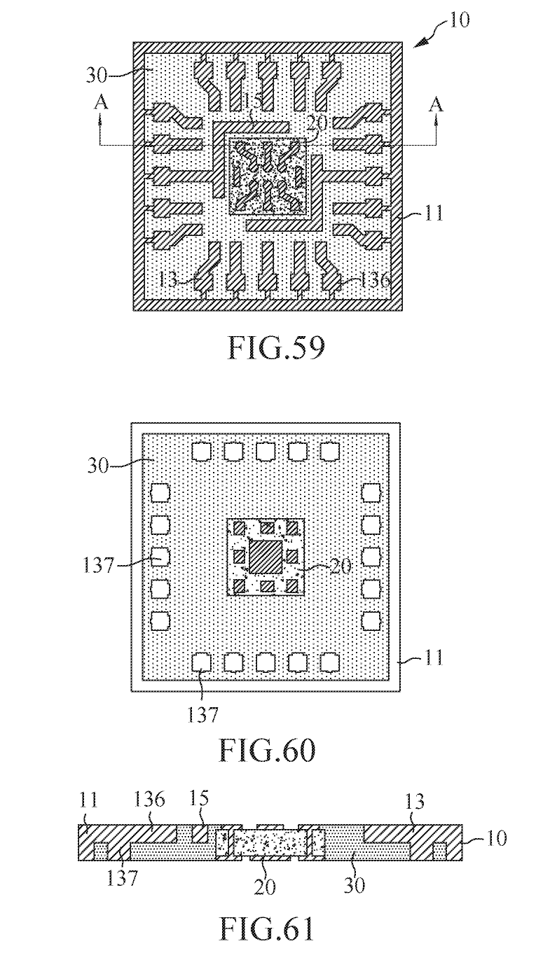

FIGS. 56-64 are schematic views showing a method of making a leadframe substrate in which the isolator includes top and bottom contact pads in accordance with the fifth embodiment of the present invention.

For purposes of brevity, any description in Embodiments above is incorporated herein insofar as the same is applicable, and the same description need not be repeated.

FIGS. 56, 57 and 58 are top plan, bottom plan and cross-sectional views, respectively, of the structure with an isolator 20 disposed at the central area of a leadframe 10. The leadframe 10 is similar to that illustrated in FIGS. 26-28, except that the alignment guide 15 is shaped into different configuration and conforms to two diagonal corners of the isolator 20. In this illustration, the isolator 20 includes a thermally conductive and electrically insulating slug 21, top contact pads 23 at the top side 201 thereof, bottom contact pads 25 at the bottom side 203 thereof, and metallized through vias 27 in contact with the top contact pads 23 and the bottom contact pads 25. The top contact pads 23 and the bottom contact pads 25 are disposed on two opposite sides of the thermally conductive and electrically insulating slug 21, respectively, and electrically connected to each other by the metallized through vias 27 that extend through the thermally conductive and electrically insulating slug 21.

FIGS. 59, 60 and 61 are top plan, bottom plan and cross-sectional views, respectively, of the structure provided with a compound layer 30. The compound layer 30 fills in spaces between the metal leads 13 and between the alignment guide 15 and the isolator 20, and further covers the horizontally elongated portions 136 of the metal leads 13 and the alignment guide 15 from below.

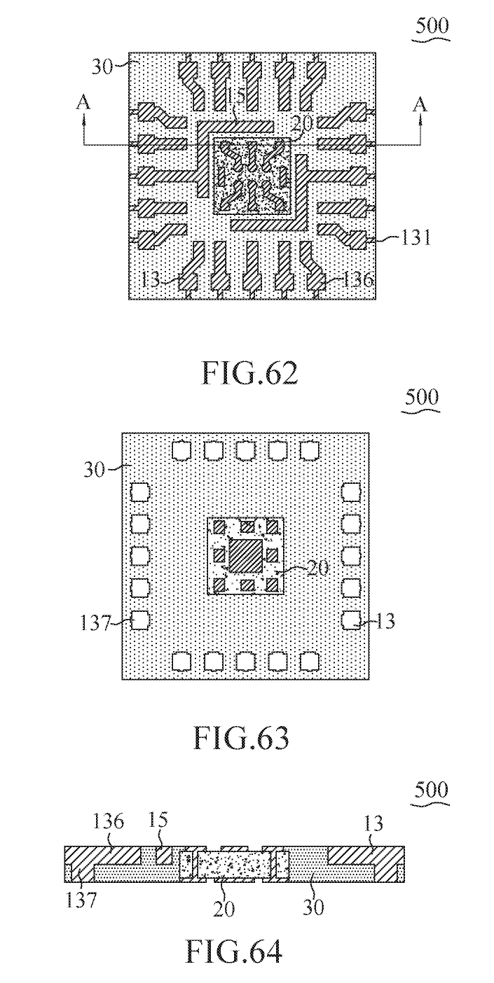

FIGS. 62, 63 and 64 are top plan, bottom plan and cross-sectional views, respectively, of a leadframe substrate 500 separated from the metal frame 11. By cutting off the metal frame 11, the metal leads 13 are electrically isolated from each other and have outer ends 131 situated at peripheral edges of the leadframe substrate 500.

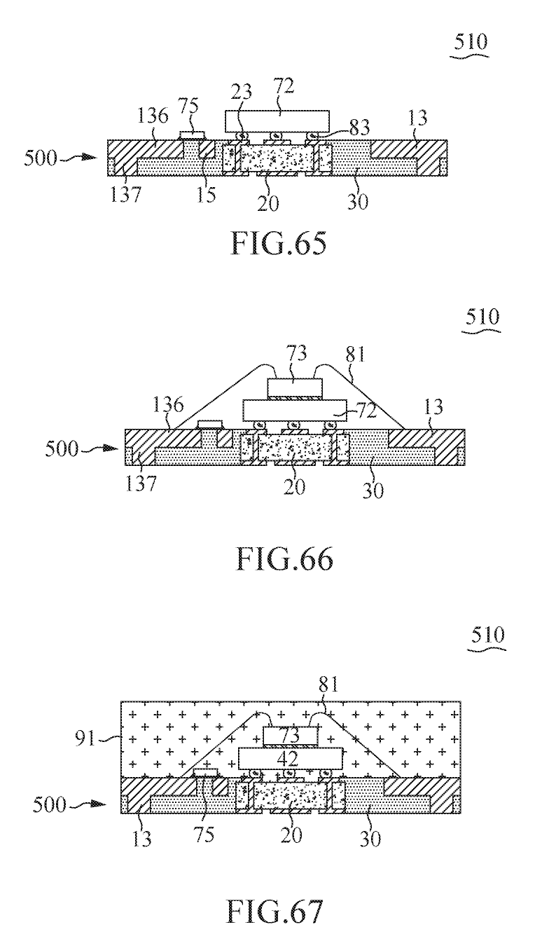

FIG. 65 is a cross-sectional view of a semiconductor assembly 510 having a first semiconductor device 72 and a passive component 75 electrically connected to the leadframe substrate 500. The first semiconductor device 72 is flip-chip mounted over the top side of the isolator 20 and electrically coupled to the top contact pads 23 of the isolator 20 via conductive bumps 83. The passive component 75 is mounted over the top surface of the compound layer 30 and electrically coupled to the metal lead 13 and the alignment guide 15.

FIG. 66 is a cross-sectional view of the semiconductor assembly 510 of FIG. 65 further provided with a second semiconductor device 73. The second semiconductor device 73 is mounted on the first semiconductor device 72 and electrically coupled to the metal leads 13 through bonding wires 81.

FIG. 67 is a cross-sectional view of the semiconductor assembly 510 of FIG. 66 further provided with an encapsulant 91. The encapsulant 91 covers the first semiconductor device 72, the second semiconductor device 73, the passive component 75 and the bonding wires 81 from above.

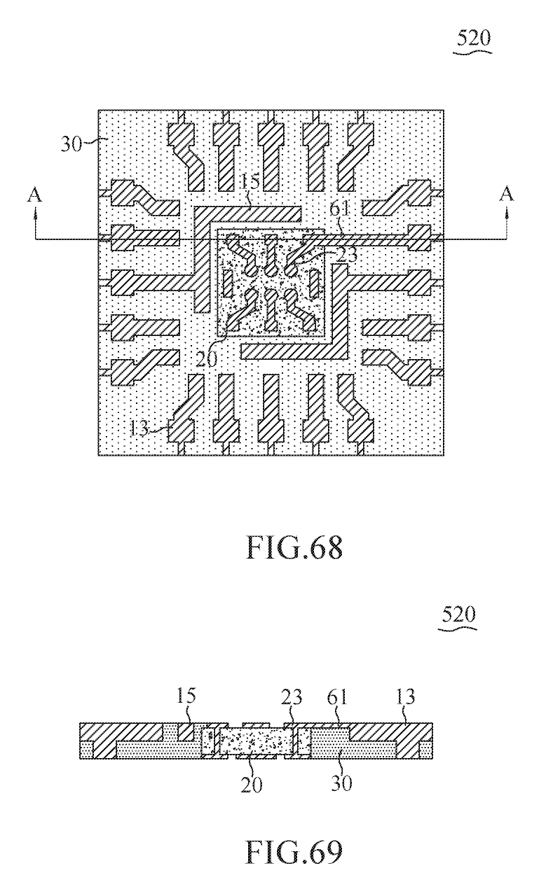

FIGS. 68 and 69 are top plan and cross-sectional views, respectively, of another aspect of the leadframe substrate according to the fifth embodiment of the present invention. The leadframe substrate 520 is similar to that illustrated in FIGS. 62-64, except that it further includes a routing circuitry 61 that laterally extends on the compound layer 30 and is electrically coupled to the metal lead 13 and the top contact pad 23 of the isolator 20.

### Embodiment 6

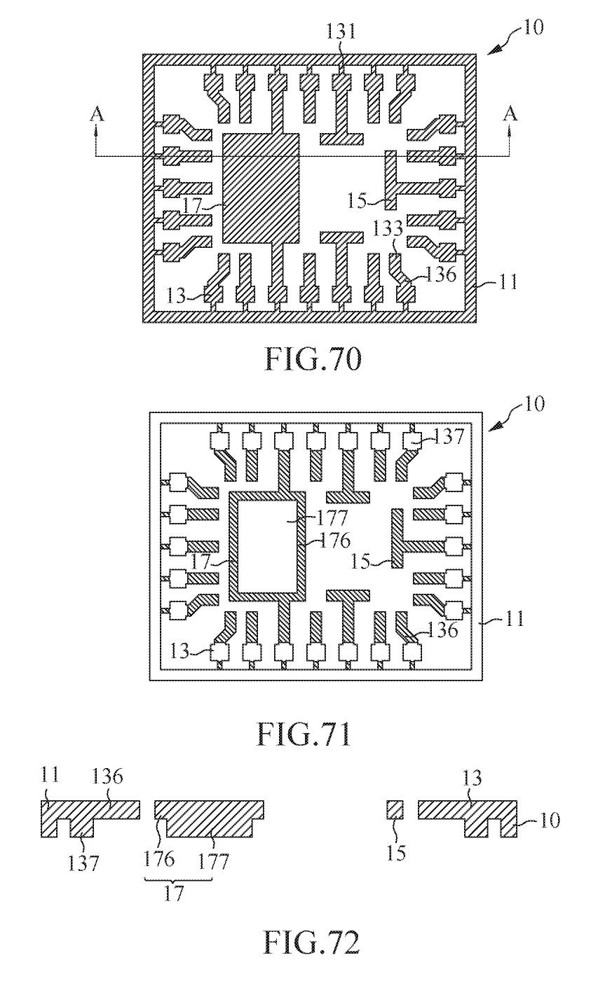

FIGS. 70-81 are schematic views showing a method of making a leadframe substrate having a metal paddle spaced from the isolator in accordance with the sixth embodiment of the present invention.

For purposes of brevity, any description in Embodiments above is incorporated herein insofar as the same is applicable, and the same description need not be repeated.

FIGS. 70, 71 and 72 are top plan, bottom plan and cross-sectional views, respectively, of a leadframe 10. In this embodiment, the leadframe 10 includes a metal frame 11, a plurality of metal leads 13, an alignment guide 15 and a metal paddle 17. The metal leads 13 each have an outer end 131 integrally connected to the metal frame 11 and an inner end 133 directed toward the metal paddle 17 and a predetermined area for the placement of a subsequently disposed isolator. The alignment guide 15 can provide the isolator placement accuracy and is connected to the metal frame 11 through the metal leads 13. The metal paddle 17 can serve as a heat spreader for chip attachment and is connected to the metal frame 11 through the metal leads 13. Additionally, the leadframe 10 is further selectively half-etched from the bottom side. As a result, the alignment guide 15 has a reduced thickness, and the metal leads 13 and the metal paddle 17 have a stepped cross-sectional profile. In this illustration, the metal leads 13 each have a horizontally elongated portion 136 and a vertically projected portion 137, whereas the metal paddle 17 has a base portion 176 and a post portion 177. The vertically projected portion 137 protrudes from a lower surface of the horizontally elongated portion 136 in the downward direction. The post portion 177 has a smaller diameter than the base portion 176 and protrudes from a lower surface of the base portion 176 in the downward direction.

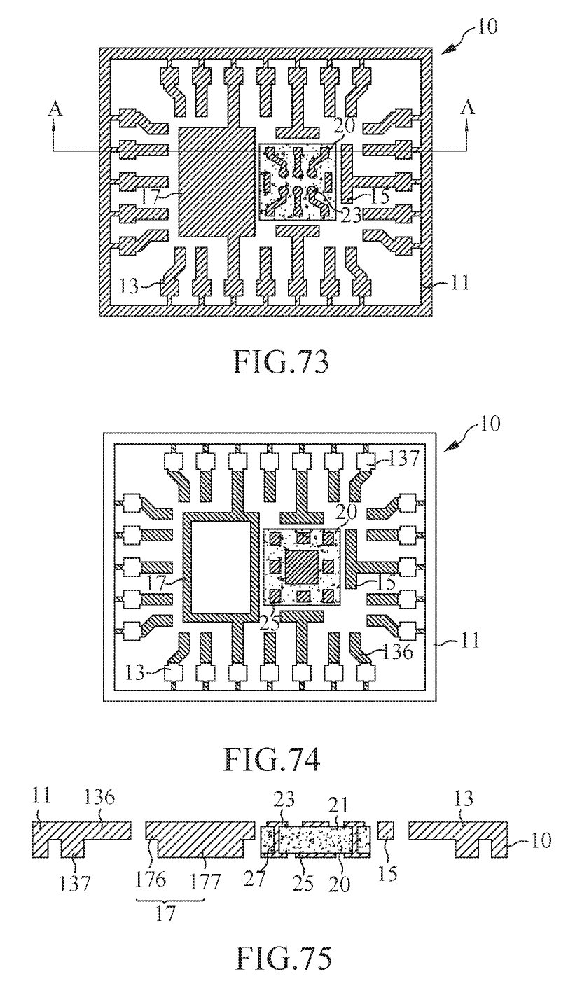

FIGS. 73, 74 and 75 are top plan, bottom plan and cross-sectional views, respectively, of the structure with an isolator 20 disposed at the predetermined area surrounded by the alignment guide 15. The isolator 20 is spaced from the alignment guide 15 and the metal paddle 17. In this illustration, the isolator 20 includes a thermally conductive and electrically insulating slug 21, top contact pads 23, bottom contact pads 25, and metallized through vias 27. The top contact pads 23 and the bottom contact pads 25 are disposed on two opposite sides of the thermally conductive and electrically insulating slug 21, respectively. The metallized through vias 27 extend through the thermally conductive and electrically insulating slug 21 and provide electrical connections between the top contact pads 23 and the bottom contact pads 25.

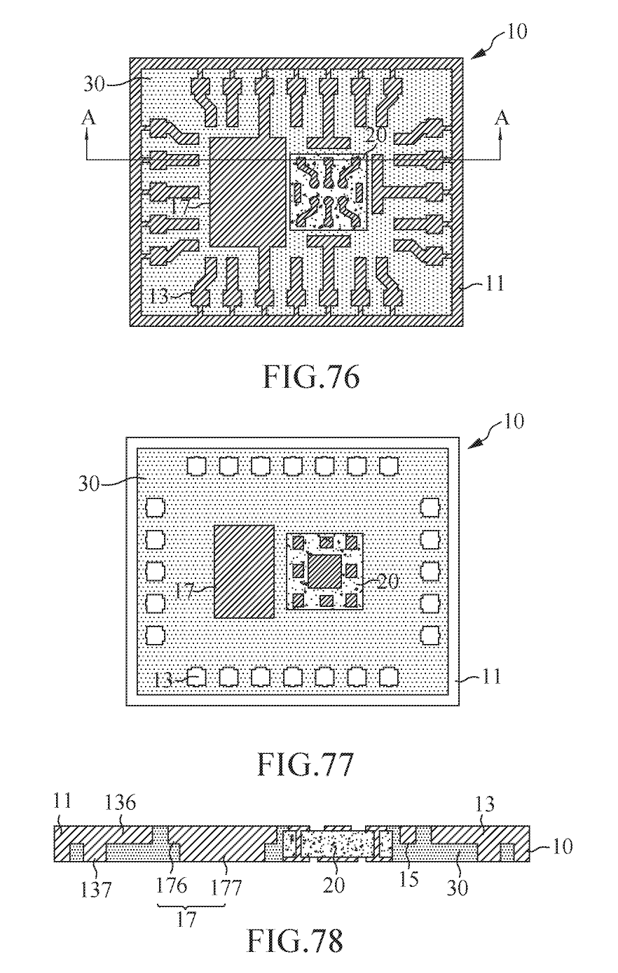

FIGS. 76, 77 and 78 are top plan, bottom plan and cross-sectional views, respectively, of the structure provided with a compound layer 30. The compound layer 30 fills in the remaining spaces within the metal frame 11 to cover sidewalls of the metal leads 13, the alignment guide 15, the metal paddle 17 and the isolator 20. By planarization, the compound layer 30 has top and bottom surfaces substantially coplanar with top and bottom sides of the metal leads 13, the metal paddle 17 and the isolator 20, respectively.

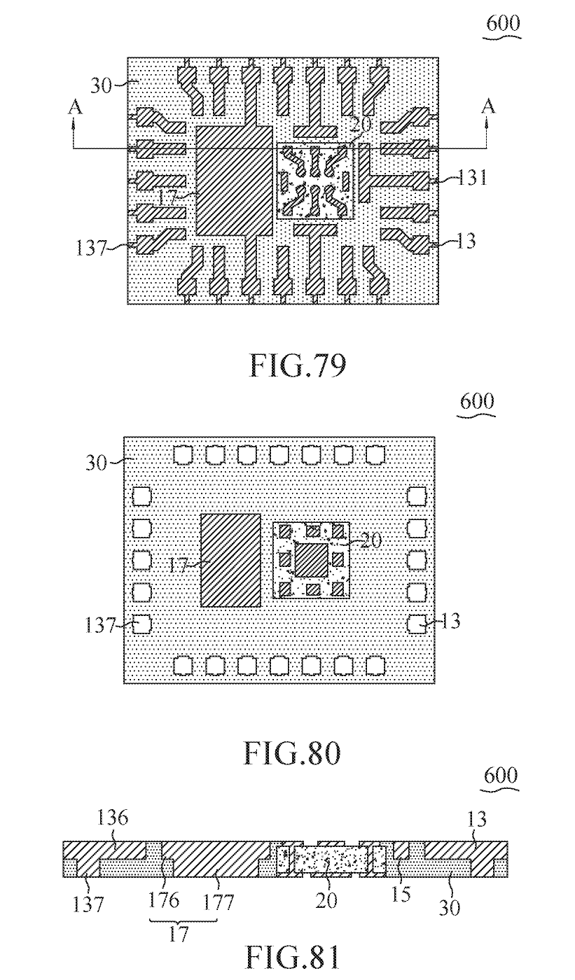

FIGS. 79, 80 and 81 are top plan, bottom plan and cross-sectional views, respectively, of a leadframe substrate 600 separated from the metal frame 11. By cutting off the metal frame 11, the connection between the outer ends 131 of the metal leads 13 is broken. In this embodiment, some of the metal leads 13 are integrated with the metal paddle 17 and provided for ground connection, whereas the others of the metal leads 13 are electrically isolated from each other and serve as signal leads.

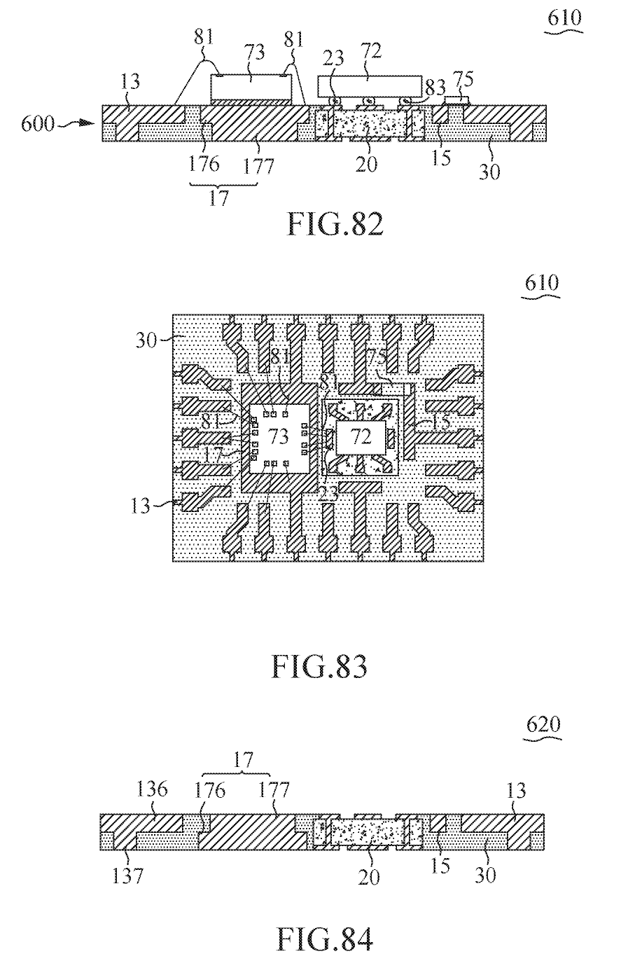

FIGS. 82 and 83 are cross-sectional and top plan views, respectively, of a semiconductor assembly 610 having a first semiconductor device 72, a second semiconductor device 73 and a passive component 75 electrically connected to the leadframe substrate 600. The first semiconductor device 72 is flip-chip mounted on the top contact pads 23 of the isolator 20 through conductive bumps 83. The second semiconductor device 73 is attached on the top side of the metal paddle 17 and electrically coupled to the metal leads 13 and the metal paddle 17 through bonding wires 81. The passive component 75 is mounted on the alignment guide 15 and electrically connected to the metal leads 13 integrated with the alignment guide 15. Further, as shown in FIG. 83, the second semiconductor device 73 is also electrically coupled to the top contact pad 23 of the isolator 20 through the bonding wires 81.

FIG. 84 is a cross-sectional view of another aspect of the leadframe substrate according to the sixth embodiment of the present invention. The leadframe substrate 620 is similar to that illustrated in FIG. 81, except that the post portion 177 protrudes from an upper surface of the base portion 176 in the upward direction. In this illustration, the base portion 176 has a lower surface flush with the bottom surface of the compound layer 30, whereas the post portion 177 has an exterior surface flush with the top surface of the compound layer 30.

### Embodiment 7

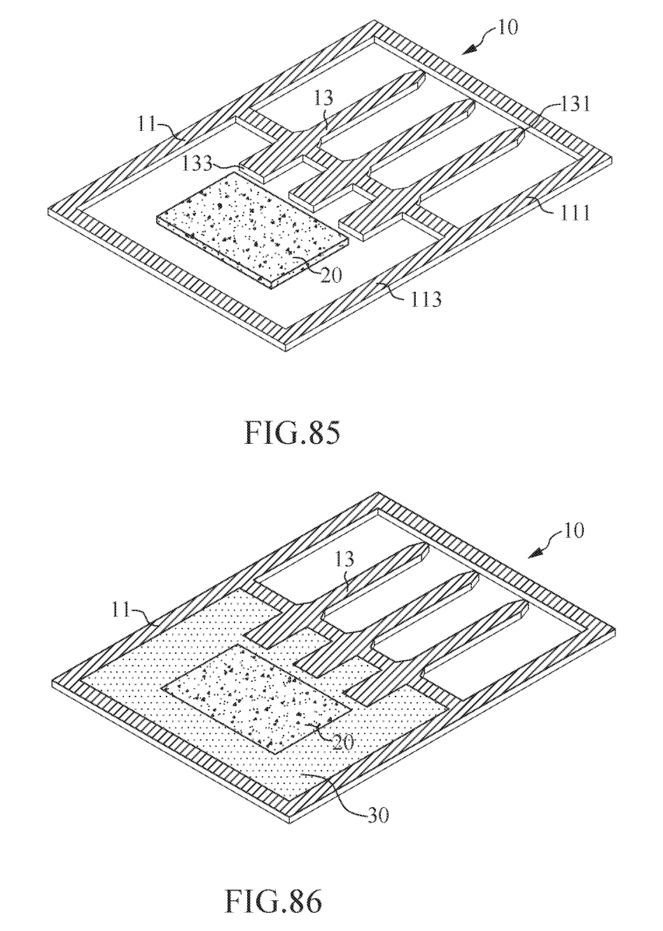

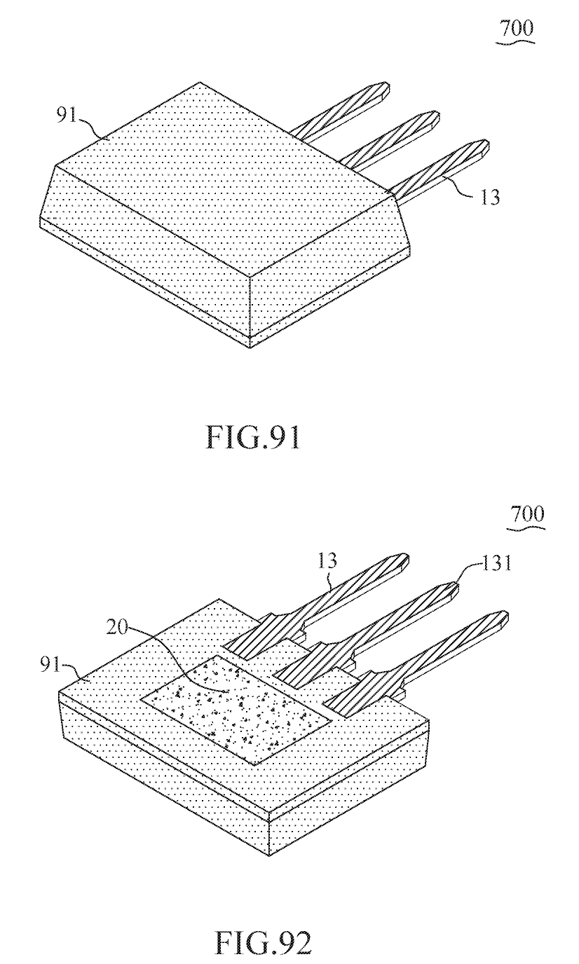

FIGS. 85-92 are schematic views showing a method of making a semiconductor assembly with pin terminals in accordance with the seventh embodiment of the present invention.

For purposes of brevity, any description in Embodiments above is incorporated herein insofar as the same is applicable, and the same description need not be repeated.

FIG. 85 is a top perspective view of the structure with an isolator 20 placed within a leadframe 10. The leadframe 10 includes a metal frame 11 and a plurality metal leads 13. In this embodiment, the metal frame 11 consists of a first ring portion 111 and a second ring portion 113, and the metal leads 13 are shaped into elongated strips parallel to each other and integrally connected to the metal frame 11. The isolator 20 is placed within the second ring portion 113 of the metal frame 11, and disposed about and spaced from the inner ends 133 of the metal leads 13.

FIG. 86 is a top perspective view of the structure provided with a compound layer 30. The compound layer 30 fills in the remaining space within the second ring portion 113 of the metal frame 11. As a result, the compound layer 30 provides robust mechanical bonds between the leadframe 10 and the isolator 20.

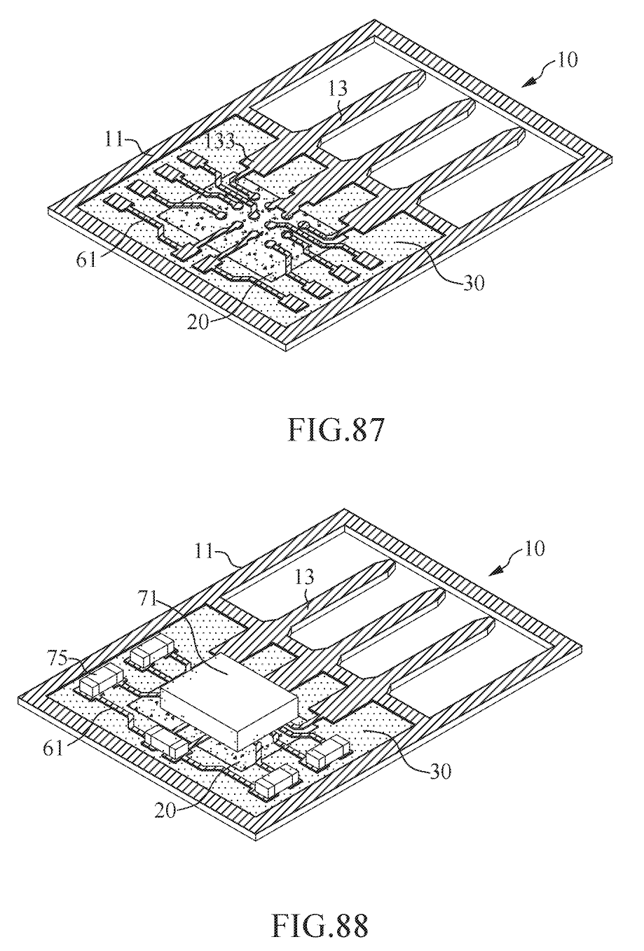

FIG. 87 is a top perspective view of the structure provided with a routing circuitry 61 by metal pattern deposition. The routing circuitry 61 laterally extends on the top surfaces of the compound layer 30 and the isolator 20, and is electrically coupled to the inner ends 133 of the metal leads 13.

FIG. 88 is a top perspective view of the structure provided with a semiconductor device 71 and passive components 75. The semiconductor device 71 is flip-chip mounted over the top surface of the isolator 20 and electrically coupled to the routing circuitry 61. The passive components 75 are mounted over the top surface of the compound layer 30 and electrically coupled to the routing circuitry 61.

FIG. 89 is a top perspective view of the structure provided with an encapsulant 91. The encapsulant 91 covers the isolator 20, the compound layer 30, the routing circuitry 61, the semiconductor device 71, the passive components 75 and selected portions of the metal leads 13 from above.

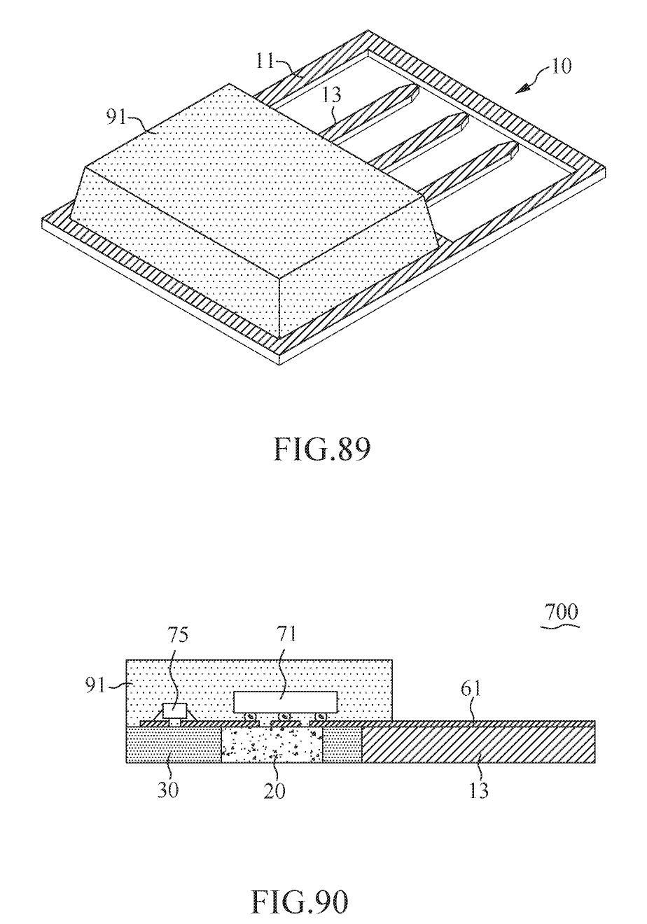

FIGS. 90, 91 and 92 are cross-sectional, top perspective and bottom perspective views, respectively, of a semiconductor assembly 700 separated from the metal frame 11. By cutting off the metal frame 11, the metal leads 13 are electrically isolated from each other. In this embodiment, the metal leads 13 laterally extend out of the peripheral edges of the encapsulant 91 to form pin terminals for external connection.

### Embodiment 8

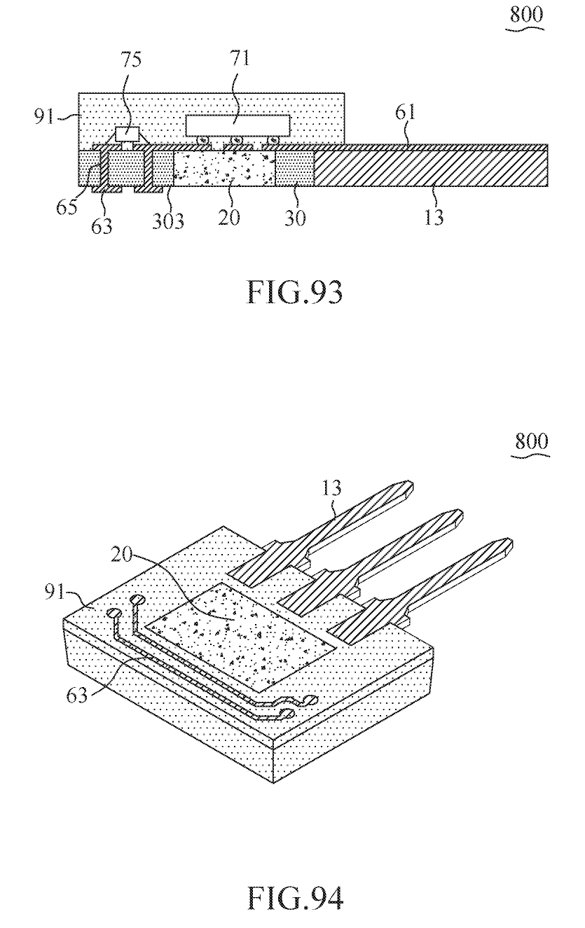

FIGS. 93 and 94 are cross-sectional and bottom perspective reviews, respectively, of a semiconductor assembly with top and bottom routing circuitries in accordance with the eighth embodiment of the present invention.

For purposes of brevity, any description in Embodiments above is incorporated herein insofar as the same is applicable, and the same description need not be repeated.

The semiconductor assembly 800 is similar to that illustrated in FIGS. 90-92, except that it further includes an additional routing circuitry 63 on the bottom surface 303 of the compound layer 30 and metallized through vias 65 in the compound layer 30. The additional routing circuitry 63 laterally extends on the bottom surface 303 of the compound layer 30, and is electrically connected to the routing circuitry 61 through the metallized through vias 65 that extend through the compound layer 30.

As illustrated in the aforementioned embodiments, a distinctive leadframe substrate is configured to have an isolator incorporated with a leadframe and exhibits improved reliability. The leadframe substrate mainly includes an isolator, a plurality of metal leads, a compound layer and an optional routing circuitry. In a preferred embodiment, the metal leads are trimmed from a leadframe and disposed about sidewalls of the isolator, with top and bottom sides of the metal leads substantially coplanar with top and bottom sides of the isolator, respectively; the compound layer covers the sidewalls of the isolator and the metal leads and provides mechanical bonds between the isolator and the metal leads; and the optional routing circuitry is deposited on the top surface of the compound layer and electrically coupled to the metal leads and optionally further laterally extends onto the top side of the isolator.

The isolator can provide a platform for device attachment and preferably has top and bottom sides not covered by the compound layer. Specifically, the isolator includes a thermally conductive and electrically insulating slug that may be made of ceramic, silicon, glass or others and typically has high elastic modulus and low coefficient of thermal expansion (for example, 2×10⁻⁶ K⁻¹ to 10×10⁻⁶ K⁻¹). As a result, the isolator, having CTE matching a semiconductor device to be assembled thereon, provides a CTE-compensated platform for the semiconductor device, and thus internal stresses caused by CTE mismatch can be largely compensated or reduced. Further, the isolator also provides primary heat conduction for the semiconductor device so that the heat generated by the semiconductor device can be conducted away. Additionally, the isolator may further include top contact pads and bottom contact pads on opposite sides of the thermally conductive and electrically insulating slug, respectively. In a preferred embodiment, the top contact pads and the bottom contact pads are electrically coupled to each other by metallized through vias that extend through the thermally conductive and electrically insulating slug. Optionally, the top contact pad of the isolator may be electrically connected to the metal lead through a routing circuitry deposited on the compound layer and in contact with the top contact pad and the metal leads. For secure bonds between the isolator and the compound layer, the isolator may have a stepped cross-sectional profile formed by a base portion and a post portion. Preferably, the base portion laterally extends beyond peripheral edges of the post portion and has a larger diameter than the post portion. The post portion can protrude from an upper side of the base portion in a vertical direction, and the compound layer covers and contacts the upper side of the base portion. Alternatively, the post portion protrudes from a lower side of the base portion in a vertical direction, and the compound layer covers and contacts the lower side of the base portion. As a result, the compound layer also has a stepped cross-sectional profile where it contacts the isolator so as to prevent the isolator from being vertically forced apart from the compound layer and also to avoid micro-cracking at the interface along the vertical direction.

The metal leads can serve as signal horizontal and vertical transduction pathways or provide ground/power plan for power delivery and return, and preferably have top and bottom sides not covered by the compound layer. Specifically, the metal leads may have horizontally elongated shape and laterally extend to be flush with the periphery of the compound layer or laterally extend beyond the periphery of the compound layer. In a preferred embodiment, the metal leads have a thickness in a range from about 0.15 mm to about 1.0 mm, which are thicker than the routing circuitry. For secure bonds between the metal leads and the compound layer, the metal leads may have a stepped cross-sectional profile formed by a horizontally elongated portion and one or more vertically projected portions. In one aspect of the present invention, the vertically projected portion protrudes from an upper side of the horizontally elongated portion, and the compound layer covers and contacts the upper side of the horizontally elongated portion. In another aspect of the present invention, the vertically projected portion protrudes from a lower side of the horizontally elongated portion, and the compound layer covers and contacts the lower side of the horizontally elongated portion. Alternatively, one or more of the vertically projected portions protrudes from an upper side of the horizontally elongated portion, and the other or others of the vertically projected portions protrudes from a lower side of the horizontally elongated portion. Accordingly, the compound layer can cover and contact the upper and lower sides of the horizontally elongated portion.

The compound layer can be deposited within the metal frame and bonded to the isolator and the metal leads by paste printing, compressive molding, transfer molding, liquid injection molding, spin coating, or other suitable methods. By planarization, the compound layer may have top and bottom surfaces substantially coplanar with the top and bottom sides of the isolator and the metal leads, respectively. Preferably, the compound layer has an elastic modulus larger than 1.0 GPa, a linear coefficient of thermal expansion in a range from about 5×10⁻⁶ K⁻¹ to about 15×10⁻⁶K⁻¹. Additionally, for sufficient thermal conductivity and suitable viscosity, the compound layer may include thermally conductive fillers in a range of 10 to 90% by weight. For instance, the thermally conductive fillers may be made of aluminum nitride (AlN), aluminum oxide, silicon carbide (SiC), tungsten carbide, boron carbide, silica or the like and preferably has relatively high thermal conductivity, high electrical resistance, and a relatively low CTE. Accordingly, the compound layer would exhibit improved heat dissipation performance, electrical isolation performance and shows inhibition of delamination or cracking of the optional routing circuitry deposited thereon or interfaces due to low CTE. Additionally, the maximum particle size of the thermally conductive fillers may be 25 μm or less.

The routing circuitry, optionally deposited on the top surface of the compound layer, preferably contacts the vertically projected portion of the metal lead, and may further extend onto the top side of the isolator. As a result, the routing circuitry can provide electrical contacts on the isolator to allow a semiconductor device to be flip-chip attached on the isolator, or provide a thermal pad on the isolator for a semiconductor device face-up mounted thereon. The routing circuitry can be formed by metal deposition using photolithographic process. Preferably, the routing circuitry is deposited by a sputtering process and then an electrolytic plating process. Optionally, another routing circuitry may be further deposited on the bottom surface of the compound layer and electrically connected to the routing circuitry on the top surface of the compound layer by metallized through vias in the compound layer. Accordingly, the double routing circuitries on two opposite sides of the compound layer can enhance routing flexibility of the leadframe substrate.

For isolator placement accuracy, an alignment guide may be further provided to be laterally aligned with and in close proximity to the sidewalls of the isolator. Accordingly, the leadframe may further include an alignment guide connected to the metal frame. The alignment guide can have patterns against undesirable movement of the isolator and define an area with the same or similar topography as the isolator and prevent the lateral displacement of the isolator. For instance, the alignment guide can be aligned along and conform to four sides, two diagonal corners or four corners of the isolator. Additionally, the leadframe may further include a metal paddle connected to the metal frame and spaced from the isolator, and the compound layer also covers sidewalls of the metal paddle. In a preferred embodiment, the metal paddle is disposed about the inner ends of the metal leads, and has top and bottom sides substantially coplanar with the top and bottom sides of the isolator and the metal leads as well as the top and bottom surfaces of the compound layer, respectively. Likewise, the metal paddle may have a stepped cross-sectional profile formed by a base portion and a post portion. Preferably, the base portion laterally extends beyond peripheral edges of the post portion and has a larger diameter than the post portion. The post portion can protrude from an upper side of the base portion in a vertical direction, and the compound layer covers and contacts the upper side of the base portion. Alternatively, the post portion protrudes from a lower side of the base portion in a vertical direction, and the compound layer covers and contacts the lower side of the base portion. As a result, the compound layer also has a stepped cross-sectional profile where it contacts the metal paddle so as to prevent the metal paddle from being vertically forced apart from the compound layer and also to avoid micro-cracking at the interface along the vertical direction.

The present invention also provides a semiconductor assembly in which a first semiconductor device such as chip is mounted over the top side of the isolator of the aforementioned leadframe substrate and electrically connected to the metal leads. Specifically, the first semiconductor device can be electrically connected to the metal leads using a wide variety of connection media including conductive bumps (such as gold or solder bumps) on the routing circuitry or the top contact pads of the isolator, or by bonding wires attached to the routing circuitry or the metal leads. Additionally, the semiconductor assembly may further include a second semiconductor device electrically connected to the leadframe substrate. For instance, the second semiconductor device mat be attached on the first semiconductor device or the metal paddle, and electrically connected to the metal leads by bonding wires attached to the routing circuitry or the metal leads.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The first and second semiconductor devices can be packaged or unpackaged chips. Furthermore, the first and second semiconductor devices can be bare chips, or wafer level packaged dies, etc.

The term “cover” refers to incomplete or complete coverage in a vertical and/or lateral direction. For instance, the compound layer covers sidewalls of the isolator and the metal leads regardless of whether another element is between the isolator and the compound layer and between the metal leads and the compound layer.

The phrases “mounted on” and “attached on” include contact and non-contact with a single or multiple support element(s). For instance, the first semiconductor device can be attached on the isolator regardless of whether the first semiconductor device is separated from the isolator by a the routing circuitry and conductive bumps.

The phrase “aligned with” refers to relative position between elements regardless of whether elements are spaced from or adjacent to one another or one element is inserted into and extends into the other element. For instance, the alignment guide is laterally aligned with the sidewalls of the isolator since an imaginary horizontal line intersects the alignment guide and the isolator, regardless of whether another element is between the alignment guide and the isolator and is intersected by the line, and regardless of whether another imaginary horizontal line intersects the isolator but not the alignment guide or intersects the alignment guide but not the isolator.

The phrase “in close proximity to” refers to a gap between elements not being wider than the maximum acceptable limit. As known in the art, when the gap between the sidewalls of the isolator and the alignment guide is not narrow enough, the isolator may not be accurately confined at a predetermined location. The maximum acceptable limit for a gap between the sidewalls of the isolator and the alignment guide can be determined depending on how accurately it is desired to dispose the isolator at the predetermined location. Thereby, the description “the alignment guide in close proximity to the sidewalls of the isolator” means that the gap between the sidewalls of the isolator and the alignment guide is narrow enough to prevent the location error of the isolator from exceeding the maximum acceptable error limit. For instance, the gaps in between the sidewalls of the isolator and the alignment guide may be in a range of about 25 to 100 microns.

The phrases “electrical connection”, “electrically connected” and “electrically coupled” refer to direct and indirect electrical connection. For instance, in a preferred embodiment, the first semiconductor device can be electrically connected to the metal leads by the routing circuitry but does not contact the metal leads.

The leadframe substrate according to the present invention has numerous advantages. The isolator provides CTE-compensated platform for the attachment of a semiconductor device and also establish a heat dissipation pathway for spreading out the heat generated by the semiconductor device. The compound layer provides robust mechanical bonds between the metal leads and the isolator. The metal leads provide primary horizontal and vertical routing, and the routing circuitry offers further routing to increase routing flexibility of the leadframe substrate. The leadframe substrate made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A leadframe substrate, comprising:
an isolator that includes a thermally conductive and electrically insulating slug;
a plurality of metal leads that are disposed about and spaced from sidewalls of the isolator, wherein the metal leads each have an inner end directed toward the sidewalls of the isolator and an outer end situated farther away from the isolator than the inner end; and
a compound layer that covers the sidewalls of the isolator and fills in spaces between the metal leads, wherein the compound layer has a top surface substantially coplanar with a top side of the isolator and top sides of the metal leads.

2. The leadframe substrate of claim 1, further comprising a routing circuitry disposed on the top surface of the compound layer and electrically coupled to at least one of the metal leads.

3. The leadframe substrate of claim 2, further comprising an additional routing circuitry disposed on a bottom surface of the compound layer and electrically connected to the routing circuitry on the top surface of the compound layer through metallized through vias in the compound layer.

4. The leadframe substrate of claim 2, wherein the routing circuitry further laterally extends onto the top side of the isolator.

5. The leadframe substrate of claim 1, wherein the isolator further includes top contact pads at the top side thereof and bottom contact pads at a bottom side thereof, and the top contact pads are electrically coupled to the bottom contact pads.

6. The leadframe substrate of claim 5, further comprising a routing circuitry disposed on the compound layer and electrically coupled to at least one of the metal leads and at least one of the top contact pads of the isolator.

7. The leadframe substrate of claim 1, further comprising an alignment guide laterally aligned with the sidewalls of the isolator and embedded in the compound layer.

8. The leadframe substrate of claim 1, wherein the metal leads each have a stepped cross-sectional profile formed by a horizontally elongated portion and at least one vertically projected portion that protrudes from an upper side or a lower side of the horizontally elongated portion in a vertical direction.

9. The leadframe substrate of claim 1, wherein the metal leads each have a stepped cross-sectional profile formed by a horizontally elongated portion, at least one vertically projected portion protruding from an upper side of the horizontally elongated portion, and at least one vertically projected portion protruding from a lower side of the horizontally elongated portion.

10. The leadframe substrate of claim 1, wherein the isolator has a stepped cross-sectional profile formed by a base portion and a post portion that has a smaller diameter than the base portion and protrudes from an upper side or a lower side of the base portion in a vertical direction.

11. The leadframe substrate of claim 1, further comprising a metal paddle disposed about and spaced from the sidewalls of the isolator, wherein the compound layer also covers sidewalls of the metal paddle, and the metal paddle has a top side substantially coplanar with the top sides of the metal leads and the top surface of the compound layer.

12. The leadframe substrate of claim 11, wherein the metal paddle has a stepped cross-sectional profile formed by a base portion and a post portion that has a smaller diameter than the base portion and protrudes from an upper side or a lower side of the base portion in a vertical direction.

13. A semiconductor assembly, comprising:
the leadframe substrate of claim 1; and
a first semiconductor device that is mounted over the top side of the isolator and electrically coupled to the leadframe substrate.

14. The semiconductor assembly of claim 13, wherein the first semiconductor device is electrically connected to the metal leads through bonding wires.

15. The semiconductor assembly of claim 13, wherein the leadframe substrate further comprises a routing circuitry that is disposed on the top surface of the compound layer and electrically coupled to at least one of the metal leads and further laterally extends onto the top side of the isolator, and the first semiconductor device is electrically coupled to the routing circuitry through conductive bumps.

16. The semiconductor assembly of claim 13, wherein the isolator further includes top contact pads at the top side thereof and bottom contact pads at a bottom side thereof, the top contact pads are electrically coupled to the bottom contact pads, and the first semiconductor device is electrically coupled to the top contact pads through conductive bumps.

17. The semiconductor assembly of claim 16, wherein the leadframe substrate further comprises a routing circuitry that is disposed on the compound layer and electrically coupled to at least one of the metal leads and at least one of the top contact pads of the isolator.

18. The semiconductor assembly of claim 16, further comprising a second semiconductor device attached on the first semiconductor device and electrically connected to the metal leads through bonding wires.

19. The semiconductor assembly of claim 13, wherein (i) the leadframe substrate further comprises a metal paddle disposed about and spaced from the sidewalls of the isolator, (ii) the compound layer also covers sidewalls of the metal paddle, (iii) the metal paddle has a top side substantially coplanar with the top sides of the metal leads and the top surface of the compound layer, and (iv) a second semiconductor device is attached to the metal paddle and electrically connected to the leadframe substrate through bonding wires.

20. A method of making a leadframe substrate with an isolator incorporated therein, the method comprising steps of:
providing a leadframe that includes a metal frame and a plurality of metal leads, wherein the metal leads are integrally connected to the metal frame and each of the metal leads has an inner end directed toward a predetermined area within the metal frame;
disposing an isolator at the predetermined area within the metal frame, wherein the isolator includes a thermally conductive and electrically insulating slug and is disposed about and spaced from the inner ends of the metal leads;
providing a compound layer that covers sidewalls of the isolator and fills in spaces between the metal leads, wherein the compound layer has a top surface substantially coplanar with a top side of the isolator and top sides of the metal leads; and
cutting off the metal frame from the metal leads.

21. The method of claim 20, further comprising a step of forming a routing circuitry on the top surface of the compound layer and electrically coupled to at least one of the metal leads.

22. The method of claim 21, further comprising a step of forming an additional routing circuitry on a bottom surface of the compound layer and electrically connected to the routing circuitry on the top surface of the compound layer through metallized through vias in the compound layer.

23. The method of claim 21, wherein the routing circuitry further laterally extends onto the top side of the isolator.

24. The method of claim 20, wherein the isolator further includes top contact pads at the top side thereof and bottom contact pads at a bottom side thereof, and the top contact pads are electrically coupled to the bottom contact pads.

25. The method of claim 24, further comprising a step of forming a routing circuitry on the compound layer and electrically coupled to at least one of the metal leads and at least one of the top contact pads of the isolator.

26. The method of claim 20, wherein the leadframe further includes an alignment guide connected to the metal frame, and the isolator is disposed at the predetermined area with the alignment guide laterally aligned with the sidewalls of the isolator.

27. The method of claim 20, wherein (i) the leadframe further includes a metal paddle connected to the metal frame and spaced from the isolator, (ii) the compound layer also covers sidewalls of the metal paddle, and (iii) the metal paddle has a top side substantially coplanar with the top sides of the metal leads and the top surface of the compound layer.
